(19) United States
(12) Patent Application Publication
(10) Pub. No.: US 2026/0033262 A1
(43) Pub. Date: Jan. 29, 2026

(54) ETCHING METHOD

(71) Applicant: Hitachi High-Tech Corporation, Minato-ku, Tokyo (JP)

(72) Inventors: Takashi HATTORI, Tokyo (JP); Masaki YAMADA, Tokyo (JP); Keisuke AKINAGA, Tokyo (JP); Aki TAKEI, Tokyo (JP); Yosuke KUROSAKI, Tokyo (JP); Hiroto OTAKE, Tokyo (JP)

(21) Appl. No.: 18/280,367

(22) PCT Filed: Dec. 19, 2022
(86) PCT No.: PCT/JP2022/046566

§ 371 Date: Oct. 17, 2025

(51) Int. Cl. H01L 21/311

(52) U.S. Cl. CPC H01L 21/31116

(57) ABSTRACT

Provided is a method that allows for the etching of a silicon nitride film with respect to a silicon oxide film with high selectivity and high precision while preventing a degradation in the shape of the silicon oxide film portion during etching. The etching method of dry etching a film structure which is formed in advance on a wafer disposed in a processing chamber and in which an end portion of a film stack including a silicon nitride film and silicon oxide films vertically sandwiching the silicon nitride film forms a sidewall of a trench or hole, by supplying a gas for processing into the processing chamber, without using plasma includes: forming, as a first process, a reaction layer on the silicon nitride film by reaction of hydrogen fluoride gas at 30° C. or higher and 55° C. or lower; removing, thereafter, as a second process, the reaction layer having been formed in the first process, through volatilization by performing heating at 70° C. or higher and 110° C. or lower without causing the hydrogen fluoride gas to flow; and etching the silicon nitride film from the end portion in a lateral direction by performing the first and second processes a plurality of times.

### TECHNICAL FIELD

The present disclosure relates to an etching method, in particular, to a process technology for isotropic dry etching used in the removal process of silicon nitride films in semiconductor elements such as 3D memories.

### BACKGROUND ART

In semiconductor devices, further miniaturization and three-dimensional structuring of device structures have been progressing to meet the demands for a reduction in power consumption and an increase in storage capacity. In manufacturing devices with three-dimensional structures, since the structures are three-dimensional and complex, in addition to “vertical (anisotropic) etching” in the related art, which performs etching in the vertical direction to a wafer surface, “isotropic etching” that also achieves etching in the lateral direction has been widely used. Hitherto, isotropic etching has been performed by wet processing using chemical solutions. However, with the advancement of miniaturization, problems such as pattern collapse caused by the surface tension of chemical solutions and an etching residue in fine gaps have become prominent. Moreover, the requirement for large-scale chemical processing is also problematic, Thus, in isotropic etching, there is a need to replace wet processing that uses chemical solutions in the related art with dry processing that does not use chemical solutions.

Since a lot of silicon nitride films are used in semiconductor devices, as dry etching processes therefor, known examples that use hydrogen fluoride (HF) gas without using plasma have been known. For example, Patent Document 1 describes a method of etching silicon nitride films without damaging thermal oxide films by supplying hydrogen fluoride gas at a wafer temperature of 60° C. or higher and 200° C. or lower. Further, Patent Document 2 describes a method of selectively etching silicon nitride films with respect to silicon oxide films by supplying hydrogen fluoride gas at a pressure of 1,333 Pa or higher in the chamber and a temperature of 10° C. to 120° C.

As known examples that use HF gas and other additional components, Patent Document 3 describes a method of selectively etching silicon nitride films by supplying NO gas and/or ozone gas along with HF gas. Further, Patent Document 4 describes a method of etching silicon nitride films through contact with a mixed gas containing a fluorine-containing carboxylic acid and HF gas at a temperature lower than 100° C. and without plasma.

As etching methods using a fluorine-containing gas other than HE gas, Patent Document 5 describes a method of selectively etching silicon nitride films with respect to silicon oxide films with CIFs gas. Further, Patent Document 6 describes a method of selectively etching silicon nitride films with a fluorine-containing etching gas selected from the group consisting of FNO, F₃NO, FNO₂, and combinations thereof. Moreover, Patent Document 7 describes etching silicon nitride films with an etching gas containing halogen fluoride that is a compound of bromine or iodine and fluorine, without using plasma, under a pressure of 1 Pa or higher and 80 kPa or lower.

As methods using radicals generated by some form of plasma, Patent Document 8 describes a method of selectively etching silicon nitride films with respect to silicon and/or silicon oxide films by supplying a fluorine-containing gas, an alcohol gas, an Oz gas, and an inert gas in the state of being excited by external plasma. Further; Patent Document 9 describes a method of selectively etching silicon nitride films, which includes the process of introducing a gas containing H and F and the process of selectively introducing radicals of an inert gas into the processing space. Moreover, Patent Document 10 describes selectively etching, from a structure in which silicon nitride films and silicon oxide films are stacked, the silicon nitride films in the lateral direction using precursors containing oxygen and precursors containing fluorine generated by plasma, at −20° C. or lower.

Further, Patent Document 6 and Patent Document 10 describe selectively etching, from the sidewall of a high-aspect-ratio opening formed in a multilayer structure in which the silicon nitride films and silicon oxide films of a 3D-NAND device, which is a 3D memory, are stacked, the silicon nitride films in the lateral direction.

Further, Patent Document 11 describes removing ammonium hexafluorosilicate [(NH₄)₂SiF₆], ammonium hydrogen fluoride [NH₄HE₂], and the like, which can be formed on a silicon nitride film, by heating with a lamp or the like.

### PRIOR ART DOCUMENT

### Patent Documents

Patent Document 1: JP-2008-187105-A
Patent Document 2: JP-2018-207088-A
Patent Document 3: JP-2014-197603-A
Patent Document 4: JP-2019-091890-A
Patent Document 5: JP-2016-58544-A
Patent Document 6: JP-2021-509538-A
Patent Document 7: WO 2021/079780
Patent Document 8: JP-2015-228433-A
Patent Document 9: JP-2019-012759-A
Patent Document 10: U.S. Pat. No. 10,319,603
Patent Document 11: JP-2005-161493-A

### SUMMARY OF THE INVENTION

### Problems to be Solved by the Invention

For example, in stacked film processing for 3D-NAND flash memories that are semiconductor elements with a three-dimensional structure and gate region processing for FinFETs, a technology for isotropically etching silicon nitride films with respect to polycrystalline silicon films or silicon oxide films with high selectivity and atomic-level controllability is required. In particular, for 3D-NAND structures, there is a process of selectively and isotropically etching, from a structure in which a lot of alternating layers of silicon oxide film (SiOg film) and silicon nitride film (SiN) are stacked and a deep hole shape or trench shape is formed in the layers, a small amount of the silicon nitride films in the lateral direction.

As described in Background Art, wet etching using hydrofluoric acid aqueous solutions or buffered hydrofluoric acid aqueous solutions in the related art has such problems as an etching residue in fine gaps and poor etching controllability. Further, in the case of dry etching, it is difficult to etch silicon nitride films with respect to silicon oxide films with high selectivity and high precision, resulting in a degradation in the desired shape of the remaining silicon oxide film portion, which is a problem.

The present disclosure has been made in view of the above-mentioned problems and provides an etching method that allows for the etching of a silicon nitride film with respect to a silicon oxide film with high selectivity and high precision without causing a degradation in the desired shape of the remaining silicon oxide film.

### Means for Solving the Problems

An etching method of the present disclosure is an etching method of dry etching a film structure which is formed in advance on a wafer disposed in a processing chamber and in which an end portion of a film stack, which includes a silicon nitride film and silicon oxide films vertically sandwiching the silicon nitride film, forms a sidewall of a trench or hole, by supplying a gas for processing into the processing chamber, without using plasma. The etching method includes: forming, as a first process, a reaction layer on the silicon nitride film by reaction of hydrogen fluoride gas at 30° C. or higher and 55° C. or lower; removing, after the first process, as a second process, the reaction layer, which has been formed in the first process, through volatilization by performing heating at 70° C. or higher and 110° C. or lower without causing the hydrogen fluoride gas to flow; and etching the silicon nitride film from the end portion in a lateral direction by performing the first process and the second process a plurality of times.

### Advantages of the Invention

According to the above-mentioned etching method, it is possible to provide the method that allows for the etching of a silicon nitride film with respect to a silicon oxide film with high selectivity and high precision while preventing a degradation in the shape of the silicon oxide film portion during etching. Problems, configurations, and effects other than the ones described above are apparent from the following description of embodiments.

### BRIEF DESCRIPTION OF THE DRAWINGS

FIG. 1A is a graph illustrating the etching film thicknesses of silicon nitride film and silicon oxide film, as well as the selectivity, with respect to the IR lamp output emitted simultaneously with HF supply in a first process according to a first embodiment (stage temperature of −30° C., total pressure of 300 Pa, and 10 cycles).

FIG. 1B is a graph illustrating the etching film thicknesses of silicon nitride film and silicon oxide film, as well as the selectivity, with respect to the IR lamp output emitted simultaneously with HF supply in the first process according to the first embodiment (stage temperature of −30° C., total pressure of 600 Pa, and 10 cycles).

FIG. 1C is a graph illustrating the etching film thicknesses of silicon nitride film and silicon oxide film, as well as the selectivity, with respect to the IR lamp output emitted simultaneously with HF supply in the first process according to the first embodiment (stage temperature of −30° C., total pressure of 900 Pa, and 10 cycles).

FIG. 2A is a graph illustrating the etching film thicknesses of silicon nitride film and silicon oxide film, as well as the selectivity, with respect to the IR lamp output emitted simultaneously with HF supply in a first process according to a second embodiment (stage temperature of −20° C., total pressure of 900 Pa, and 10 cycles).

FIG. 2B is a graph illustrating the etching film thicknesses of silicon nitride film and silicon oxide film, as well as the selectivity, with respect to the IR lamp output emitted simultaneously with HF supply in the first process according to the second embodiment (stage temperature of 0° C., total pressure of 900 Pa, and 10 cycles).

FIG. 2C is a graph illustrating the etching film thicknesses of silicon nitride film and silicon oxide film, as well as the selectivity, with respect to the IR lamp output emitted simultaneously with HF supply in the first process according to the second embodiment (stage temperature of 20° C., total pressure of 900 Pa, and 10 cycles).

FIG. 2D is a graph illustrating the etching film thicknesses of silicon nitride film and silicon oxide film, as well as the selectivity, with respect to the emission time of the emission of the IR lamp in a second process according to the second embodiment (stage temperature of 0° C., total pressure of 900 Pa, and 10 cycles).

FIG. 2E is a graph illustrating the thickness of the reaction layer on a silicon nitride film with respect to the number of cycles with different levels of the IR lamp output emitted simultaneously with HF supply in the first process according to the second embodiment.

FIG. 3A is a graph illustrating the etching film thicknesses of silicon nitride film and silicon oxide film, as well as the selectivity, with different stage temperatures in a first process according to a third embodiment.

FIG. 3B is a graph illustrating the thickness of the reaction layer on a silicon nitride film with respect to the number of cycles with different stage temperatures in the first process according to the third embodiment.

FIG. 4 is a sectional view illustrating an overview of an etching processing apparatus according to the first embodiment . . .

FIG. 5 is a flow chart of an etching method for a silicon nitride film according to the embodiment.

FIG. 6 is a flow chart of an etching method for a silicon nitride film according to the embodiment.

FIG. 7 is a time chart schematically illustrating a flow of operations with the passage of time of etching processing according to a first example.

FIG. 8 is a time chart schematically illustrating a flow of operations with the passage of time of etching processing according to a second example.

FIG. 9 is a time chart schematically illustrating a flow of operations with the passage of time of etching processing according to a third example.

FIG. 10A is a partial sectional view illustrating the progress of etching processing (before etching) for a film stack of silicon nitride film and silicon oxide film according to the example.

FIG. 10B is a partial sectional view illustrating the progress of etching processing (after etching) for the film stack of the silicon nitride film and silicon oxide film according to the example.

FIG. 11A is a partial sectional view illustrating the progress of etching processing for the film stack of the silicon nitride film and silicon oxide film when the selectivity is poor according to the example and illustrates a case where the shape of the end portion of the silicon oxide film after etching has become rounded instead of rectangular.

FIG. 11B is a partial sectional view illustrating the progress of etching processing for the film stack of the silicon nitride film and silicon oxide film according to the example and illustrates a case where the corners of the silicon oxide film have been rounded off to form a triangular shape.

FIG. 12 is a partial sectional view illustrating the progress of etching processing for the film stack of the silicon nitride film and silicon oxide film according to the example and illustrates a case with relatively high selectivity where while the corners of the silicon oxide film have remained to maintain the rectangular shape, the film thickness of the silicon oxide film portion has been thinned.

FIG. 13 is a sectional view illustrating an overview of an etching processing apparatus according to the second example.

### MODES FOR CARRYING OUT THE INVENTION

The present discloser has considered the etching of monolayer films of silicon nitride film and silicon oxide film formed by plasma chemical vapor deposition (CVD), with hydrogen fluoride gas (HF) without using plasma.

Now, examples of embodiments are described in detail with reference to the drawings.

### Example 1

### [Overall Configuration of Etching Processing Apparatus 1]

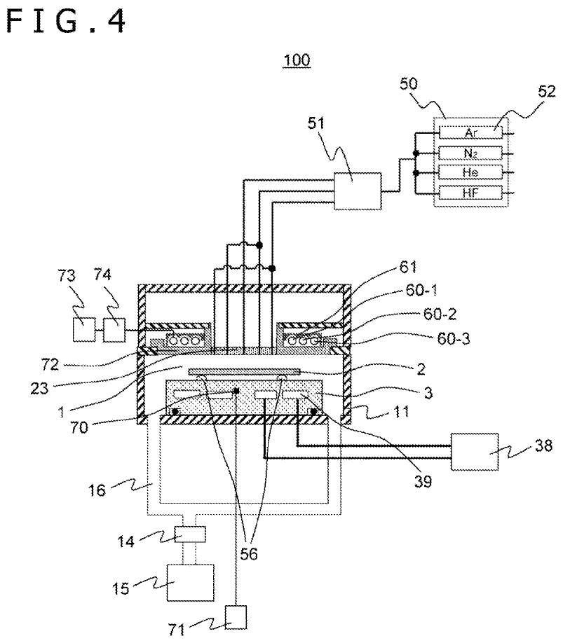

First, an overview of an etching processing apparatus according to Example 1 and its overall configuration are described with reference to FIG. 4. FIG. 4 is a sectional view illustrating an overview of an etching processing apparatus according to a first embodiment. An etching processing apparatus 100 includes a processing chamber 1. The processing chamber 1 includes a base chamber 11 and has installed therein a wafer stage 3 for placing a wafer 2. A shower plate 23 is installed in the upper center portion of the processing chamber 1, and the processing gas is supplied to the processing chamber 1 through the shower plate 23.

The supply flow rate of the processing gas is adjusted by a mass flow controller 50 installed for each gas type. Further, downstream of the mass flow controller 50, a gas distributor 51 is installed to enable independent control of the flow rates and compositions of gases supplied to the central and peripheral regions of the processing chamber 1, thereby enabling detailed control of the spatial distribution of the partial pressures of the processing gases. Note that, in FIG. 4, argon (Ar) gas, nitrogen (Na) gas, helium (He) gas, and hydrogen fluoride (HF) gas are illustrated as examples, but other processing gases can also be supplied.

To reduce the pressure in the processing chamber 1, the lower portion of the processing chamber 1 is connected to exhaust means 15 by a vacuum exhaust pipe 16. The exhaust means 15 includes, for example, a turbomolecular pump, a mechanical booster pump, or a dry pump. Further, pressure adjustment means 14 is installed upstream of the exhaust means 15 to adjust the pressure in the processing chamber 1.

Above the wafer stage 3, an IR lamp unit (infrared lighting unit) for heating the wafer 2 is installed. The IR lamp unit mainly includes an IR lamp 60, a reflecting plate 61, and an IR light transmission window 72. A circle-shaped (round-shaped) lamp is used for the IR lamp 60. Note that, the light emitted from the IR lamp 60 is light mainly including light ranging from visible light to light in the infrared region (herein referred to as “IR light”). In the present example, lamps 60-1, 60-2, and 60-3 for three cycles are installed, but lamps for two cycles, four cycles, or the like may be installed. Above the IR lamp 60, the reflecting plate 61 for reflecting IR light downward (in the direction in which the wafer 2 is installed) is installed. As the material of the IR light transmission window 72, a heat-resistant material that does not contain alkali metal ions or the like and allows the transmission of light in the infrared region is desired, and as the specific material, quartz is desired.

The IR lamp 60 is connected to an IR lamp power supply 73, and a high-frequency cut filter 74 is installed in between to prevent high-frequency power noise from flowing into the IR lamp power supply 73. Further, the IR lamp power supply 73 has a function that enables independent control of the power supplied to the IR lamps 60-1, 60-2, and 60-3, thereby enabling adjustment of the radial distribution of the amount of heating on the wafer 2 (the illustration of the wiring is partially omitted). A space for installing the shower plate 23 for processing gas introduction is formed in the center of the IR lamp unit.

The wafer stage 3 has formed therein a flow path 39 for a coolant for cooling the stage, and the coolant is circulated and supplied by a chiller 38. As this chiller, in the present embodiment, a chiller capable of controlling the temperature of the wafer stage 3 between −50° C. and 50° C., for example, was used. Further, as the type of the wafer stage 3, a wafer stage of a proximity cooling type was used here.

The surface of the wafer stage 3 is provided with protrusions 56, and the wafer 2 is mounted in a point-supported manner by the protrusions 56. The height of the protrusions 56 is desirably approximately 0.1 mm to approximately 1.0 mm, and the number of support points (that is, the number of the protrusions 56) is desirably three or more, for example. Here, specifically, the six protrusions 56 with a height of 0.25 mm were used. As the material of the wafer stage 3, a corrosion-resistant metal or metal compound with high thermal conductivity can be used.

Due to the gap created by the protrusions 56 between the wafer stage 3 and the wafer 2, when an inert gas such as He, Ar, or Na is caused to flow throughout the chamber 11, the inert gas flows into the gap, conducts heat, and cools the wafer 2. Note that, as the cooling method for the wafer 2, the electrostatic adsorption method described in Example 2 can be used.

Further, inside the wafer stage 3, a thermocouple 70 for measuring the temperature of the stage 3 is installed, and the thermocouple 70 is connected to a thermocouple thermometer 71. The temperature of the stage 3 had a difference within +1° C. from the set temperature of the chiller 38, from the thermocouple thermometer 71 based on the thermocouple 70.

The stage 3 of the proximity cooling type described above has the advantage of being able to be reduced in cost due to its simple structure. However, when the chamber 11 is in the vacuum state, which corresponds to the idling state, since the wafer 2 is insulated, it takes a certain amount of time for cooling to start by causing an inert gas to flow. Further, it was found that due to the relatively long distance between the coolant from the chiller 38 and the wafer 2, the actual temperature of the wafer 2 tended to be higher than the set temperature of the chiller 38. When the temperature of the wafer having attached thereto a thermocouple was measured during cooling or processing, it was found that the actual temperature of the wafer 2 was approximately 5° C. higher than the set temperature of the chiller 38.

Note that, as the mechanism for cooling the stage 3 used in the etching processing apparatus 100 of the present embodiment, other than a mechanism configured to circulate a coolant, a Peltier element, which is a thermoelectric conversion device, or the like can also be used.

The etching processing apparatus 100 used in the present embodiment can heat the elements inside the chamber 11 other than the wafer stage 3 that is exposed to hydrogen fluoride gas, such as the processing chamber 1. For example, as the temperature, a temperature of approximately 40° C. to approximately 120° C. can be used. This makes it possible to prevent hydrogen fluoride gas from being adsorbed inside the chamber 11 and reduce the internal corrosion of the chamber 11 as much as possible.

In the present embodiment, for example, HF at 50 Pa to 1,000 Pa (50 Pa or higher and 1,000 Pa or lower) is used with the stage 3 at a stage temperature of 40° C. to −30° C. It is conceivable that depending on the stage temperature of the stage 3, HF condenses and liquefies on the silicon nitride film. Thus, in a case where an electrostatic adsorption method is used, when HF solidifies or liquefies also on the back surface of the wafer 2, there is a possibility that the seal band for backside cooling gas of the wafer 2 breaks and a cooling gas such as He leaks, for example, thereby causing an electrostatic chuck error. In contrast to this, the stage 3 of the proximity cooling type illustrated in FIG. 4 originally had the gap created by the protrusions 56 between the wafer stage 3 and the wafer 2, and hence even when HF solidified or liquefied, no error occurred in the wafer stage 3 and stable processing was possible.

Moreover, with an electrostatic adsorption method, due to the narrow space between the wafer 2 and the stage 3, when HF liquefies, the wafer 2 tends to adhere to the stage 3 with the surface tension. Thus, in de-chucking the wafer 2, the wafer 2 may break when the wafer 2 is lifted with a pusher pin, which is a problem. In contrast to this, by employing the proximity cooling type with a gap of 0.25 mm between the wafer 2 and the stage 3 in this case, the problem of the wafer 2 adhering to the stage 3 due to liquefaction of HF was able to be reduced.

In the application of processes using low temperatures as in the present embodiment, there is a possibility that condensation occurs on the structural components in contact with the atmosphere inside the electrostatic chuck electrode, which serves as the cooling source, thereby causing short circuits in electrical circuits such as the power supply unit. Also from that perspective, the structure of the stage 3 of the proximity cooling type, which includes the electrode with the simplified internal components, is advantageous.

### [Etching Method: Process Flow of Dry Etching]

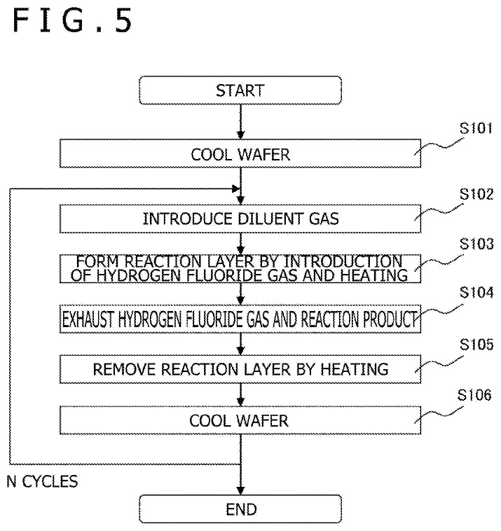

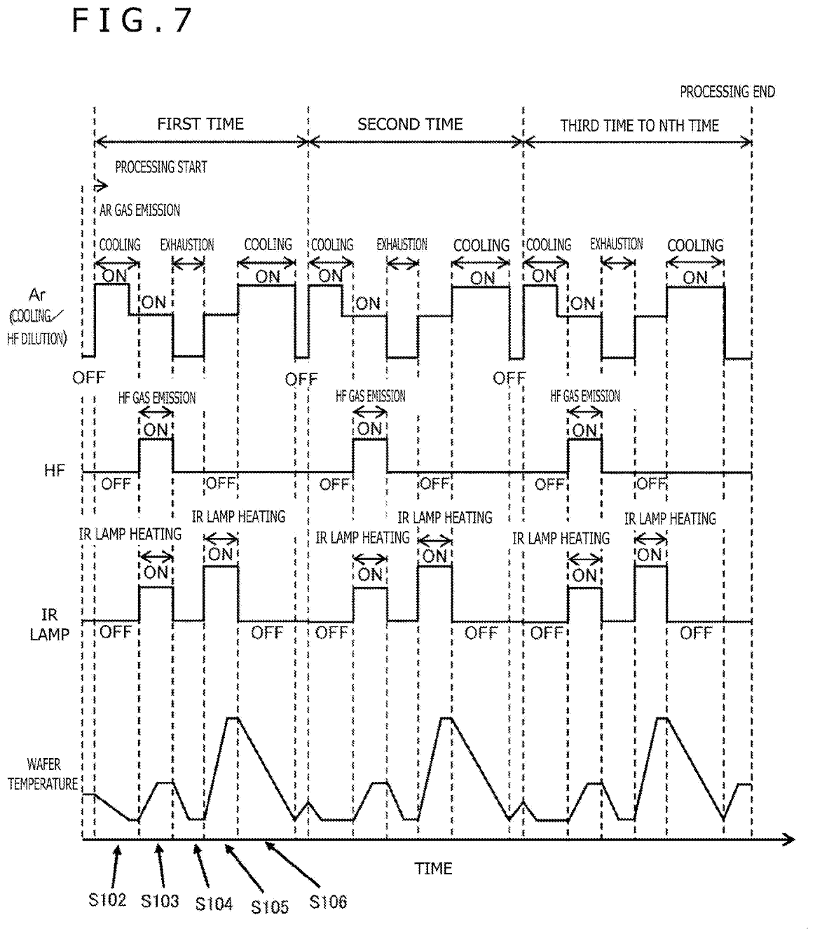

Next, a flow of the processes of dry etching with hydrogen fluoride gas without using plasma, which is proposed in the present embodiment, is described with reference to FIG. 4, FIG. 5, and FIG. 7. FIG. 5 is a flow chart of an etching method for a silicon nitride film according to the embodiment. FIG. 7 is a time chart schematically illustrating a flow of operations with the passage of time of etching processing according to the first example.

First, the wafer 2 is transferred to the processing chamber 1 through a transfer port (not illustrated) provided in the processing chamber 1, and then the wafer 2 is loaded (placed) on the protrusions 56 of the wafer stage 3.

After that, Ar gas for wafer cooling is supplied to the wafer 2 through the mass flow controller 50, the gas distributor 51, and the shower plate 23, to thereby perform water cooling in Step S101 of FIG. 5. Since Ar gas plays both the role of heat conduction to the wafer 2 and the role of a diluent gas for diluting HE gas, here, Step S101 and Step S102 of FIG. 5 are performed simultaneously. Note that, the flow rate of Ar gas can be changed (set to different flow rates) for the cooling of the wafer 2 and for use as a diluent gas. Further, it is possible to continue causing Ar gas for dilution to flow until the etching processing ends or to stop the flow. Further, instead of Ar gas, N₂ gas can be used as an inert gas.

Subsequently, as Step S103 of FIG. 5, a predetermined amount of HF gas was supplied to the processing chamber 1 as a gas for processing for a predetermined time, and the wafer 2 was simultaneously heated to form a reaction layer on the wafer 2. As the heating method, here, heating with the infrared (IR) lamp 60 was used. The wafer temperature of the wafer 2 obtained as a result of cooling with the stage 3 and heating with the IR lamp 60 is desirably 30° C. or higher and 55° C. or lower, and more desirably 35° C. or higher and 50° C. or lower, for example. As described in an example with different conditions described later, it is possible to control the film thickness of the reaction layer by controlling the total pressure or the HE partial pressure, the heating temperature, the time, and the number of repetitions, as well as the output of the IR lamp 60 in this case, for example. Further, when the wafer temperature of the wafer 2 described above is lower than 30° C., for example, the reaction layer cannot be formed adequately, which makes it difficult for etching to occur. In contrast, when the wafer temperature of the wafer 2 described above is higher than 55° C., the reaction layer can be excessively formed. The adjacent silicon oxide film is undesirably etched when the excessively formed reaction layer is decomposed and volatilized, resulting in a decrease in etching selectivity.

In the present embodiment, the pressure used is desirably approximately 10 Pa to approximately 1,000 Pa, more desirably 50 Pa to 1,000 Pa (50 Pa or higher and 1,000 Pa or lower), and particularly desirably 100 Pa to 1,000 Pa, for example. The higher the pressure, the easier it is to form a reaction layer on the silicon nitride film and the lower the required temperature for formation. Even with a higher pressure, by controlling the output of the IR lamp 60, it is possible to form a reaction layer on the silicon nitride film without affecting the silicon oxide film.

After a predetermined time for the formation of the reaction layer, as Step S104 of FIG. 5, the supply of HF gas is stopped, and the residual HE gas in the gas phase and the reaction product present on the silicon nitride film as the reaction layer are exhausted using the exhaust means 15. When vacuum exhaustion is performed, it is desirable to achieve 5 Pa or lower, for example. In Step S104, by supplying Ar gas, which is a diluent gas, during and after the exhaustion, the reaction product can be more efficiently exhausted. When exhaustion is performed while causing Ar to flow, it is desirable to achieve 40 Pa or lower, for example.

Next, heating is performed without causing HF gas to flow to remove the reaction layer (Step S105 of FIG. 5). The heating temperature here is desirably 70° C. to 110° C. (70° C. or higher and 110° C. or lower), and more desirably 70° C. to 100° C. (70° C. or higher and 100° C. or lower), for example. As the heating method, here, the IR lamp 60 was used. The heating method is not limited to this and may be, for example, a method of heating the wafer stage 3 or a method of separately transferring the wafer 2 to an apparatus configured to perform only heating, thereby performing heating processing. Further, during the emission of the IR lamp 60, Ar gas or nitrogen gas can be introduced into the processing chamber 1. Further, heating processing can be performed a plurality of times as needed. After heating, wafer cooling in Step S106 is performed. After this, the cycle including the processes in Step S102 to Step S106 is repeated N times (N is a positive integer). After repeating the cycle until the required etching amount is obtained, the etching method of FIG. 4 ends.

The time chart of FIG. 7 illustrates the flow of the etching method illustrated in FIG. 5. The process of performing heating with the IR lamp 60 while causing HE gas to flow (Step S103) and the process of performing heating with the IR lamp 60 without causing HF gas to flow (Step S105) are included in one cycle, and the cycle is repeated N times to etch the silicon nitride film.

### [Etching Result 1]

The result of etching with hydrogen fluoride (HF) gas without using plasma of the present embodiment is described. The etching rates of monolayer films of silicon nitride film (PE-SiN) and silicon oxide film (PE-SiO2) formed by plasma CVD were measured with the stage 3 at a set temperature of −30° C.

Here, as the base wafer 2, there was used a base wafer obtained by adhering coupon samples of 2 cm square of silicon nitride film and silicon oxide film to a high-resistance substrate (31 Ωcm) with a diameter of 300 mm using silicone vacuum grease.

After the above-mentioned wafer 2 had been put in the processing chamber 1 of the etching processing apparatus 100 illustrated in FIG. 4, etching was performed along the process flow of the etching method illustrated in FIG. 5. First, for wafer cooling, Ar was caused to flow at a flow rate of 1.4 L/min and 900 Pa for 60 seconds. After that, after the set pressure had been reached, while HF was introduced at a flow rate of 0.40 L/min and Ar was introduced as a diluent gas at a flow rate of 0.20 L/min, the emission of the IR lamp 60 was simultaneously performed at a predetermined output. Here, the time for HF introduction and IR emission was 60 seconds. With this, a reaction layer is formed on the silicon nitride film.

After that, with an exhaust valve in the pressure adjustment means 14 fully open, exhaustion was performed for 120 seconds. With this exhaustion operation, some of the fluorine gas and reaction product are exhausted. Next, with the stage 3 at the set temperature unchanged, Ar gas caused to flow at a flow rate of 0.50 L/min, and the exhaust valve in the pressure adjustment means 14 fully open, heating was performed with the IR lamp 60 at a predetermined lamp intensity for 30 seconds to 50 seconds. With this, the reaction layer is removed. After that, the processing returned to the start, and the wafer 2 was cooled with Ar caused to flow at a pressure of 900 Pa and a flow rate of 1.4 L/min for 60 seconds. This series of processes (processes in Step S102 to Step S106) was performed for 10 cycles here along the flow of FIG. 5.

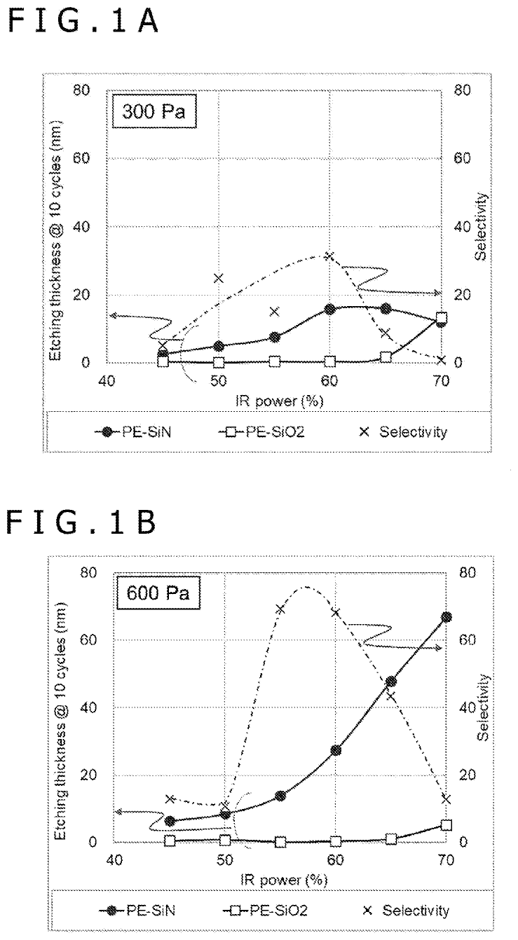

The etching film thickness of the silicon nitride film (PE-SiN) and the etching film thickness of the silicon oxide film (PE-SiO2) obtained after 10 cycles, as well as the selectivity of the silicon nitride film with respect to the silicon oxide film, with respect to different outputs of the IR lamp 60, are illustrated in FIG. 1A, FIG. 1B, and FIG. 1C. FIG. 1A is a graph illustrating the etching film thicknesses of silicon nitride film and silicon oxide film, as well as the selectivity, with respect to the IR lamp output emitted simultaneously with HF supply in a first process according to the first embodiment (stage temperature of −30° C., total pressure of 300 Pa, and 10 cycles). FIG. 1B is a graph illustrating the etching film thicknesses of silicon nitride film and silicon oxide film, as well as the selectivity, with respect to the IR lamp output emitted simultaneously with HF supply in the first process according to the first embodiment (stage temperature of −30° C., total pressure of 600 Pa, and 10 cycles). FIG. 1C is a graph illustrating the etching film thicknesses of silicon nitride film and silicon oxide filma, as well as the selectivity, with respect to the IR lamp output emitted simultaneously with HF supply in the first process according to the first embodiment (stage temperature of −30° C., total pressure of 90 Pa, and 10 cycles). Here, FIG. 1A, FIG. 1B, and FIG. 1C illustrate the experimental results for the respective different pressures during the introduction of HE/Ar and IR emission, namely, 300 Pa, 600 Pa, and 900 Pa. Further, IR lamp emission for removing the reaction layer formed in the second process (S103) was performed at an output of 70% for 50 seconds.

As illustrated in FIG. 1A, in a case where 300 Pa was used, when an IR output of 60% or higher was used, an etching amount of approximately 15 nm of the silicon nitride film (PE-SiN) was obtained by 10 cycles. However, it was found that at an IR output of 65% or higher, the silicon oxide film (PE-SiO2) also began to etch, resulting in a decrease in selectivity.

As illustrated in FIG. 1B, when the pressure was increased to 600 Pa, the etching amount of the silicon nitride film (PE-SiN) increased proportionally to the IR lamp output. By increasing the pressure, the etching amount of the silicon nitride film (PE-SiN) increases overall, and the selectivity with respect to the silicon oxide film (PE-SiO2) increases. However, also in this case, the silicon oxide film (PE-SiO2) begins to etch at an IR output of 65% or higher. Moreover, it was found that, as illustrated in FIG. 1C, also when the pressure was increased to 900 Pa, as the IR output increased, the etching amount of the silicon nitride film (PE-SiN) tended to increase, leading to a further increase in etching amount.

With the use of the wafer 2 having attached thereto a thermocouple, the process temperatures during lamp emission were actually measured by substituting HF gas with Ar. Table 1A describes the IR lamp output (IR output: 50%, 55%, 60%, and 65%) and the temperature of the wafer 2 after 60 seconds for a stage temperature of −30° C. Here, the reached temperatures are described. The same high-resistance substrate as the base wafer is used. The measured temperatures were from 30° C. to 57° C. Further, the temperatures in the reaction layer removal process were also measured, and it was found that the temperatures reached 80° C.

TABLE 1A

| | | | | |
|---|---|---|---|---|
| IR output (%) | 50 | 55 | 60 | 65 |
| Temperature (° C.) | 30 | 38 | 53 | 57 |

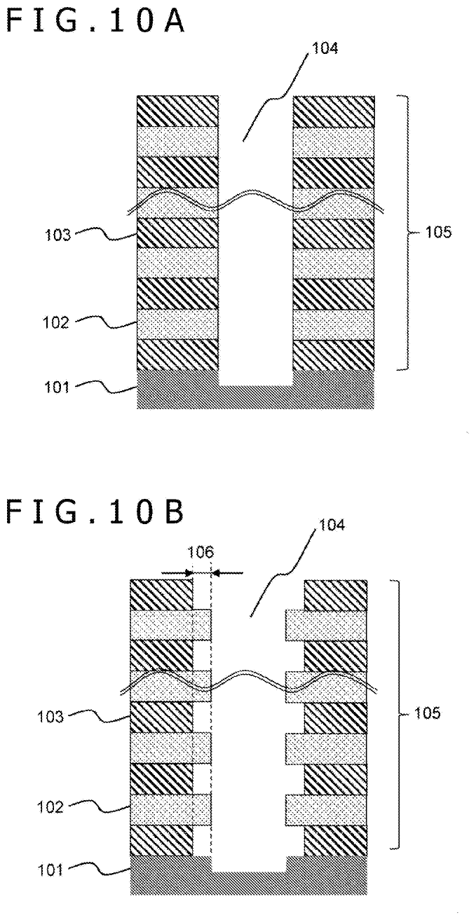

The structure of the film targeted by the present embodiment is described with reference to FIG. 10A and FIG. 10B. FIG. 10A is a partial sectional view illustrating the progress of etching processing (before etching) for a film stack of silicon nitride film and silicon oxide film according to the example. FIG. 10B is a partial sectional view illustrating the progress of etching processing (after etching) for the film stack of the silicon nitride film and silicon oxide film according to the example. The structure of the film targeted by the present embodiment is a structure required for 3D-NAND in which a lot of alternating layers of the silicon nitride film 103 and the silicon oxide film 102 are stacked on the substrate 101 and a deep hole shape or trench shape is formed in the layers as an opening 104, as illustrated in FIG. 10A. That is, this configuration is a film structure in which the end portion of a film stack, which includes silicon nitride films and silicon oxide films vertically sandwiching the silicon nitride films, forms the sidewall of a trench or hole. The film thickness of the silicon nitride film 103 used here is from several nm to 100 nm, and the film thickness of the silicon oxide film 102 is from several nm to 100 nm. Further, such a stack includes several tens to several hundreds of stacked layers. A total thickness 105 of these stacked layers is from several μm to several tens of μm. The width of the opening 104 is from several tens of nm to several hundreds of nm. By the process of the present embodiment, as illustrated in FIG. 10B, the silicon nitride film 103 is etched with respect to the silicon oxidefilm 102 in the lateral direction with high selectivity. A lateral etching dimension 106 is several nm to several tens of nm.

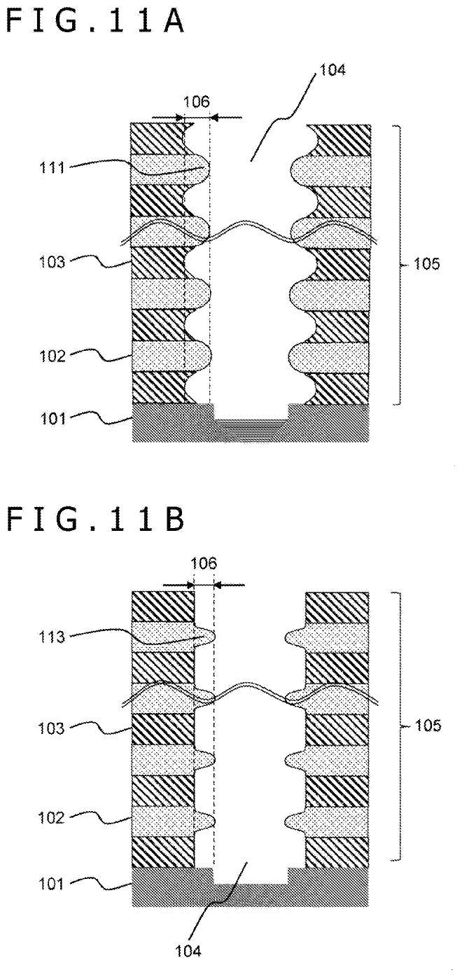

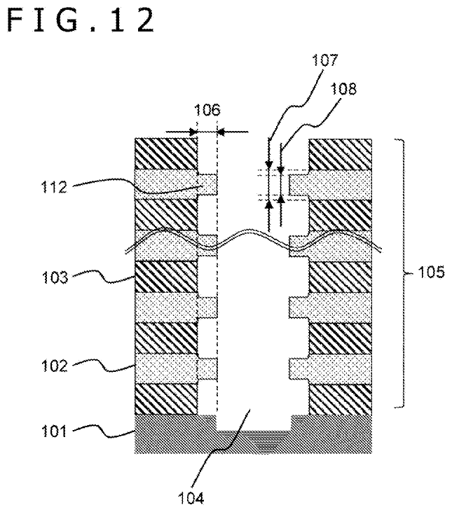

FIG. 11A, FIG. 11B, and FIG. 12 are diagrams illustrating exemplary shapes of the end portion of the silicon oxide film 102 after etching. FIG. 11A is a partial sectional view illustrating the progress of etching processing for the film stack of the silicon nitride film and silicon oxide film when the selectivity is poor according to the example and illustrates a case where the shape of the end portion of the silicon oxide film after etching has become rounded instead of rectangular. FIG. 11B is a partial sectional view illustrating the progress of etching processing for the film stack of the silicon nitride film and silicon oxide film according to the example and illustrates a case where the corners of the silicon oxide film have been rounded off to form a triangular shape. FIG. 12 is a partial sectional view illustrating the progress of etching processing for the film stack of the silicon nitride film and silicon oxide film according to the example and illustrates a case with relatively high selectivity where while the corners of the silicon oxide film have remained to maintain the rectangular shape, the film thickness of the silicon oxide film portion has been thinned.

Here, in etching the silicon nitride film 103 in the lateral direction, the selectivity with respect to the silicon oxide film 102 is desirably 10 or higher, and more desirably 20 or higher. When this selectivity is low, the portion of the silicon oxide film 102, which is not intended to be etched originally, is etched simultaneously, and hence the shape of the end portion of the silicon oxide film 102 after etching is not rectangular but rounded, as indicated by 111 of FIG. 11A, which adversely affects the device performance.

Empirically, when the selectivity is 10 or higher, and more desirably 20 or higher, a shape closer to a rectangle as illustrated in FIG. 10B is obtained. Further, when the selectivity is lower than 5, the shape of the end portion of the silicon oxide film 102 is rounded as indicated by 111 of FIG. 11A, which is undesirable.

Here, with the use of a sample obtained by forming a 200 nm slit-shaped space (opening 104) in a sample including a total of 20 alternating layers of the silicon nitride film 103 (film thickness of 40 nm) and the silicon oxide film 102 (film thickness of 40 nm), the etching characteristics with fine patterns were evaluated. Etching was performed for 10 cycles under the experimental conditions of the conditions illustrated in FIG. 1A, FIG. 1B, and FIG. 1C. The results are described in Table 1B, Table 1C, and Table 1D. Table 1B describes the etching results at a stage temperature of −30° C. and 300 Pa. Table 1C describes the etching results at a stage temperature of −30° C. and 600 Pa. Table 1D describes the etching results at a stage temperature of −30° C. and 900 Pa. Table 1E describes the symbols for the evaluation results of the slit sample and the criteria therefor.

As a result, when the etching of the silicon nitride film 103 progressed with high selectivity and a shape closer to a rectangle as illustrated in FIG. 10B, there was a case where the selectivity was poor and the distal end of the silicon oxide film 102, which was intended to remain rectangular, was rounded as illustrated in FIG. 11A (indicated by 111). There was observed a case where although the selectivity was relatively good, the corners of the silicon oxide film 102 were rounded off to form a triangular shape as illustrated in FIG. 11B (indicated by 113). Moreover, there was observed a result in which while the corners of the silicon oxide film 102 remained to maintain the rectangular shape, the film thickness of the distal end portion of the silicon oxide film 102 was thinned as illustrated in FIG. 12 (indicated by 112). 112 of FIG. 12 is an illustration of an exemplary end portion of the silicon oxide film 102 after etching, in which while the corners of the silicon oxide film 102 have remained to maintain the rectangular shape, the film thickness of the portion of the silicon oxide film 102 has been thinned. 113 of FIG. 11B is an illustration of an exemplary end portion of the silicon oxide film 102 after etching, in which the corners of the silicon oxide film 102 have been rounded off to form a triangular shape. The composition formula of the silicon oxide film is represented as SiO₂ or SiO2.

Thus, Table 1B, Table 1C, and Table 1D describe the recess amount (obtained by subtracting the etching amount of the silicon oxide film from the etching amount of the silicon nitride film), the selectivity based on the result of the slit pattern (obtained by dividing the etching amount from the initial dimensions of the silicon nitride film by the etching amount of the silicon oxide film), and the remaining SiO2 thickness (obtained by dividing a thickness 108 of the distal end of the silicon oxide film 102 after etching illustrated in FIG. 12 by an initial thickness 107 of the silicon oxide film 102). Here, good etching conditions include a relatively large recess amount, high selectivity, and a remaining SiO2 thickness with a value close to 1.

Note that, to make the evaluation results easier to understand, symbols such as ⊚, ∘, Δ, and x are included in Table 1B, Table 1C, and Table 1D. The criteria for the symbols are described in Table 1E.

TABLE 1B

| | | | |
|---|---|---|---|
| IR output (%) | 60 | 65 | 70 |
| Temperature (° C.) | 53 | 57 | 59 |
| Recess amount (nm) | ⊚ 37.5 | ⊚ 61.0 | ⊚ 62.5 |
| Selectivity | ◯ 9.95 | ◯ 8.50 | ◯ 9.17 |
| Remaining SiO2 | ◯ 0.833 | X 0.667 | X 0.538 |
| thickness | | | |

TABLE 1C

| | | | |
|---|---|---|---|
| IR output (%) | 55 | 60 | 65 |
| Temperature (° C.) | 38 | 53 | 57 |
| Recess amount (nm) | ⊚ 34.0 | ⊚ 64.8 | ⊚ 72.4 |
| Selectivity | ⊚ 22.1 | ◯ 8.93 | ⊚ 14.1 |
| Remaining SiO2 | ◯ 0.833 | Δ 0.792 | X 0.708 |
| thickness | | | |

TABLE 1D

| | | | | |
|---|---|---|---|---|
| IR output (%) | 50 | 55 | 60 | 65 |
| Temperature (° C.) | 30 | 38 | 53 | 57 |
| Recess amount (nm) | ⊚ 25.8 | ⊚ 38.0 | ⊚ 60.5 | ⊚ 65.2 |
| Selectivity | ◯ 6.12 | ◯ 5.90 | ◯ 9.16 | ◯ 9.51 |
| Remaining SiO2 | ◯ 0.833 | ◯ 0.833 | Δ 0.792 | X 0.708 |
| thickness | | | | |

TABLE 1E

| Symbol | X | Δ | ○ | ⊙ |
|---|---|---|---|---|
| Recess amount (nm) | <5 | <10 | <20 | >20 |
| Selectivity | <5 | — | 5 to 10 | 10< |
| Remaining Sio2 | <0.75 | 0.75 to | 0.80 to | 0.90< |
| thickness | | 0.80 | 0.90 | |

As described in Table 1B, Table 1C, and Table 1D, in all cases, when the IR lamp output (IR output) is high, the remaining SiO2 thickness is small. It was found that a high IR lamp output was not suitable for a condition. Thus, it was found that the remaining SiO2 thickness was small in some cases even when the selectivity was relatively high. From the above, it was found that the temperature that achieved the satisfactory recess amount, selectivity, and remaining SiO2 thickness was 30° C. or higher and 55° C. or lower.

Further, it was found that although both high temperature and high pressure contributed to an increase in the etching amount of the silicon nitride film 103, good characteristics were obtained when high pressure and relatively low temperature were used since as the temperature increased, the remaining SiO2 thickness decreased.

### Example 2

### [Etching Processing Apparatus 2]

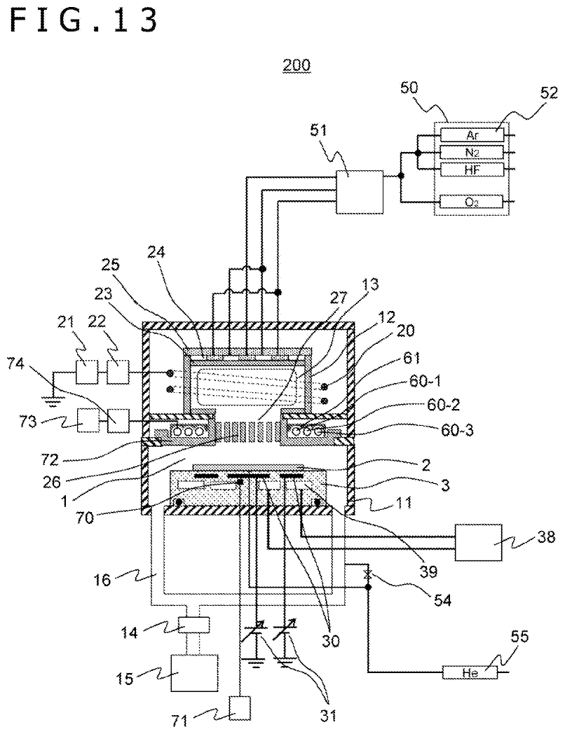

Next, an overview of an etching processing apparatus 200 according to Example 2 of the present embodiment and its overall configuration are described with reference to FIG. 13. FIG. 13 is a sectional view illustrating an overview of the etching processing apparatus according to the second example. The etching processing apparatus 200 includes the processing chamber 1. The processing chamber 1 includes the base chamber 11 and has installed therein the wafer stage 3 for placing the wafer 2. Above the processing chamber 1, a plasma source is installed, and an ICP discharge method is used. The ICP plasma source can be used for cleaning the inner wall of the chamber 11 with plasma and generating reactive gases with plasma. A cylindrical quartz chamber 12, which forms the ICP plasma source, is installed above the processing chamber 1, and an ICP coil 20 is installed outside the quartz chamber 12. The ICP coil 20 is connected to a high-frequency power supply 21 for plasma generation through a matching unit 22. The frequency of the high-frequency power generated by the high-frequency power supply 21 is in the frequency band of several tens of MHz, such as 13.56 MHz. A top plate 25 is installed above the quartz chamber 12. Below the top plate 25, a gas dispersion plate 24 and the shower plate 23 are installed, and the processing gas is introduced into the quartz chamber 12 through the gas dispersion plate 24 and the shower plate 23.

The supply flow rate of the processing gas is adjusted by the mass flow controller 50 installed for each gas type. Further, downstream of the mass flow controller 50, the gas distributor 51 is installed to enable independent control of the flow rates and compositions of gases supplied to the central and peripheral regions of the quartz chamber 12, thereby enabling detailed control of the spatial distribution of the partial pressures of the processing gases. Note that, in FIG. 13, Ar, N₂, HF, and O₂ are illustrated as processing gases, but other gases can be supplied as needed.

To reduce the pressure in the processing chamber, the lower portion of the processing chamber 1 is connected to the exhaust means 15 by the vacuum exhaust pipe 16. The exhaust means 15 includes, for example, a turbomolecular pump, a mechanical booster pump, or a dry pump. Further, the pressure adjustment means 14 is installed upstream of the exhaust means 15 to adjust the pressure in the processing chamber 1.

Above the wafer stage 3, an IR lamp unit for heating the wafer 2 is installed. The IR lamp unit mainly includes the IR lamp 60, the reflecting plate 61, and the IR Light transmission window 72. A circle-shaped (round-shaped) lamp is used for the IR lamp 60. Note that, the light emitted from the IR lamp is light mainly including light ranging from visible light to light in the infrared region (herein referred to as “IR light”). In the present example, the lamps 60-1, 60-2, and 60-3 for three cycles are installed, but lamps for two cycles, four cycles, or the like may be installed. Above the IR lamp 60, the reflecting plate 61 for reflecting IR light downward (in the direction in which the wafer is installed) is installed. As the material of the IR light transmission window 72, a heat-resistant material that does not contain alkali metal ions or the like and allows the transmission of light in the infrared region is desired, and as the specific material, quartz is desired.

The IR lamp 60 is connected to the IR lamp power supply 73, and the high-frequency cut filter 74 is installed in between to prevent high-frequency power noise from flowing into the IR lamp power supply 73. Further, the IR lamp power supply 73 has installed therein a function that enables independent control of the power supplied to the IR lamps 60-1, 60-2, and 60-3, thereby enabling adjustment of the radial distribution of the amount of heating on the wafer 2 (the illustration of the wiring is partially omitted).

In the center of the IR lamp unit, a flow path 27 is formed. In the flow path 27, there is installed a slit plate 26 with a plurality of holes for shielding ions and electrons generated in the plasma and allowing only neutral gas and neutral radicals to pass through to be emitted on the wafer 2. As the material of the slit plate 26, a heat-resistant material that does not contain alkali metal ions or the like is desired, and as the specific material, alumina or quartz can be used.

The wafer stage 3 has formed therein the flow path 39 for a coolant for cooling the stage, and the coolant is circulated and supplied by the chiller 38. As the chiller 38, in the present embodiment, a chiller capable of controlling the temperature of the wafer stage 3 between-50° C. and 50° C. was used. Further, to fix the wafer 2 by electrostatic adsorption, plate-shaped electrode plates 30 are embedded in the stage 3, and the electrode plates 30 are each connected to a DC power supply 31. Further, to efficiently cool the wafer 2, the space between the back surface of the wafer 2 and the wafer stage 3 can be supplied with He gas. Further, to prevent the back surface of the wafer 2 from being scratched even when the wafer 2 is heated or cooled while being adsorbed, the front surface of the wafer stage 3 (the surface on which the wafer 2 is mounted) is coated with a resin such as polyimide. Further, inside the wafer stage 3, the thermocouple 70 for measuring the temperature of the stage 3 is installed, and the thermocouple 70 is connected to the thermocouple thermometer 71.

With respect to the set temperature of the chiller 38, the temperature of the stage 3 from the thermocouple thermometer 71 based on the thermocouple 70 had a difference within 11° C., and the temperature of the wafer 2 separately measured by the thermocouple 70 had a difference within ±3° C. (within ±2° C. with respect to the temperature of the stage 3).

Note that, as the mechanism for cooling the stage 3 used in the etching processing apparatus 200 of the present embodiment, other than a mechanism configured to circulate a coolant, a Peltier element, which is a thermoelectric conversion device, or the like can also be used.

Further, the etching processing apparatus 200 used in the present embodiment can heat the elements inside the chamber 11 other than the wafer stage 3 that is exposed to hydrogen fluoride gas, such as the processing chamber 1. For example, as the temperature, a temperature of approximately 40° C. to approximately 120° C. can be used. This makes it possible to prevent hydrogen fluoride gas from being adsorbed inside the chamber 11 and reduce the internal corrosion of the chamber as much as possible.

### [Etching Method: Process Flow 2 of Dry Etching]

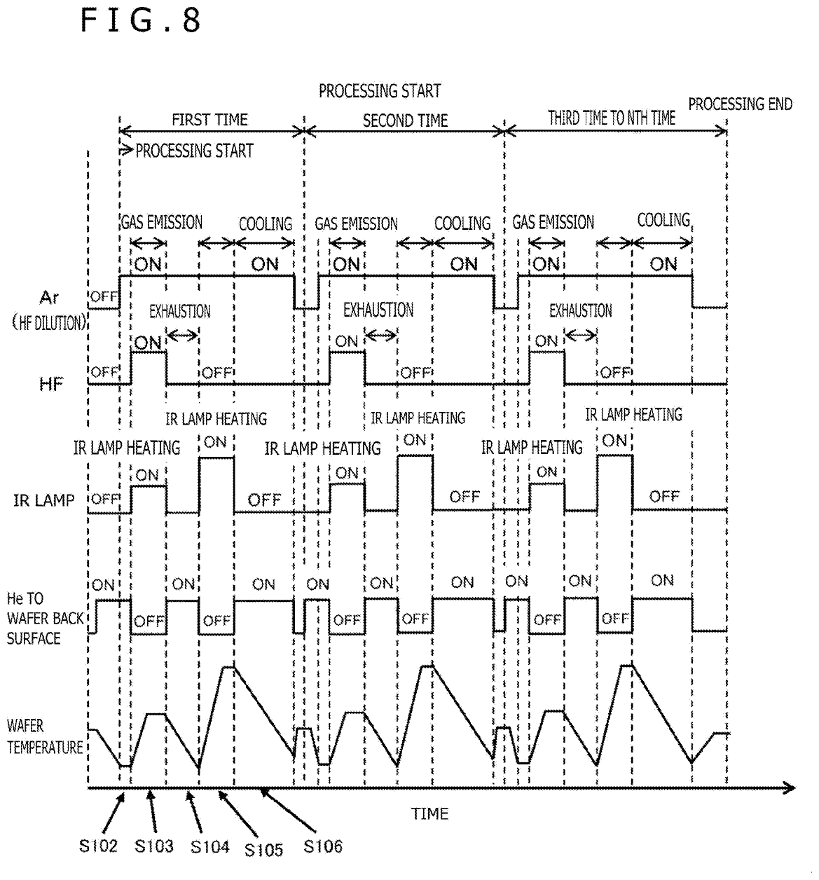

Next, a flow of an etching process with hydrogen fluoride gas without using plasma, which is proposed in the present embodiment, is described with reference to FIG. 5, FIG. 8, and FIG. 13 (apparatus diagram). FIG. 5 is a flow chart of an etching method for a silicon nitride film according to the embodiment. FIG. 8 is a time chart schematically illustrating a flow of operations with the passage of time of etching processing according to the second example.

First, the wafer 2 is transferred to the processing chamber 1 through the transfer port (not illustrated) provided in the processing chamber 1. Then, the wafer 2 is fixed to the wafer stage 3 by the DC power supply 31 for electrostatic adsorption, and He gas 55 for wafer cooling is supplied to the back surface of the wafer 2, to thereby perform wafer cooling in Step S101 of FIG. 5. A valve 54 is provided between the He gas 55 and the vacuum exhaust pipe 16.

Next, as Step S102 of FIG. 5, Ar gas for diluting HF gas is supplied to the processing chamber 1 through the mass flow controller 50, the gas distributor 51, and the shower plate 23. It is possible to continue causing Ar gas for dilution to flow until the etching processing ends or to stop the flow. Further, instead of Ar gas, Na gas can be used as an inert gas.

Subsequently, as Step S103 of FIG. 5, a predetermined amount of HF gas was supplied to the processing chamber 1 as a gas for processing for a predetermined time, and heating was simultaneously performed to form a reaction layer. As the heating method, here, heating with the infrared (IR) lamp 60 was used. The temperature of the wafer 2 obtained as a result of cooling with the stage 3 and heating with the IR lamp 60 is desirably 30° C. or higher and 55° C. or lower, and more desirably 35° C. or higher and 50° C. or lower, for example. As described in the example with different conditions described later, it is possible to control the film thickness of the reaction layer by controlling the total pressure or the HE partial pressure, the heating temperature, the time, and the number of repetitions, as well as the lamp output of the IR lamp 60 in this case, for example.

In the present embodiment, the pressure used is desirably approximately 10 Pa to approximately 1,000 Pa, more desirably 50 Pa to 1,000 Pa (50 Pa or higher and 1,000 Pa or lower), and particularly desirably 100 Pa to 1,000 Pa. The higher the pressure, the easier it is to form a reaction layer on the silicon nitride film 103 and the lower the required temperature for formation. Even with a higher pressure, by controlling the output of the IR lamp 60, it is possible to form a reaction layer on the silicon nitride film 103 without affecting the silicon oxide film 102.

After a predetermined time for the formation of the reaction layer, as Step S104 of FIG. 5, the supply of HF gas is stopped, and the residual HF gas in the gas phase and the reaction product present on the silicon nitride film 103 as the reaction layer are exhausted. In Step S104, by supplying Ar gas, which is a diluent gas, during and after the exhaustion, the reaction product can be more efficiently exhausted.

Next, heating is performed without causing HF gas to flow to remove the reaction layer (Step S105 of FIG. 5). The heating temperature here is desirably 70° C. to 110° C. (70° C. or higher and 110° C. or lower), and more desirably 70° C. to 100° C. (70° C. or higher and 100° C. or lower), for example. As the heating method, here, the IR lamp 60 was used. The heating method is not limited to this and may be, for example, a method of heating the wafer stage 3 or a method of separately transferring the wafer 2 to an apparatus configured to perform only heating, thereby performing heating processing. Further, during the emission of the IR lamp 60, Ar gas or nitrogen gas can be introduced. Further, heating processing can be performed a plurality of times as needed. After heating, wafer cooling in Step S106 is performed. After this, the cycle including the processes in Step S102 to Step S106 is repeated N times (N is a positive integer). After repeating the cycle until the required etching amount is obtained, the etching method ends.

The time chart of FIG. 8 illustrates the flow illustrated in FIG. 5. The process of performing IR lamp heating while causing HF gas to flow (Step S103) and the process of performing IR lamp heating without causing HF gas to flow (Step S105) are included in one cycle, and the cycle is repeated N times to etch the silicon nitride film.

### [Etching Result 2]

With the use of the etching processing apparatus 200 illustrated in FIG. 13 and the process flow of FIG. 5 and FIG. 8 described earlier, etching was performed under different conditions. In Example 1, the experiments were performed with the fixed flow rate of HF/Ar=0.40/0.20 (L/min), the fixed stage temperature of −30° C., and different total pressures of 300 Pa, 600 Pa, and 900 Pa. In Example 2, with the fixed total pressure of 900 Pa, the Same flow rates of HF and Ar, and different stage temperatures of the stage 3, namely, −20° C., 0° C., and 20° C., similar to Example 1, etching with hydrogen fluoride gas without using plasma of the present embodiment was performed. Further, during etching, for example, a voltage of 11,200 V was applied to electrostatically adsorb the wafer 2 onto the stage 3. Further, to improve the thermal conduction in the stage 3, He was caused to flow from the back surface of the wafer 2 to achieve a pressure of 1.0 kPa, for example.

After the flow rate of Ar had been set to 1.0 L/min and the pressure had been set to 900 Pa, while HE was introduced at a flow rate of 0.40 L/min and Ar was introduced as a diluent gas at a flow rate of 0.20 L/min, the emission of the IR lamp 60 was simultaneously performed at a predetermined output. Here, the time for HF introduction and IR emission was 60 seconds. With this, a reaction layer is formed on the silicon nitride film 103.

After that, with the exhaust valve in the pressure adjustment means 14 fully open, exhaustion was performed for 120 seconds. With this exhaustion operation, some of the fluorine gas and reaction product are exhausted. Next, with the stage 3 at the set temperature unchanged, Ar caused to flow at a flow rate of 0.50 L/min, and the exhaust valve in the pressure adjustment means 14 fully open, heating was performed with the IR lamp 60 at a predetermined lamp intensity for 30 seconds to 50 seconds. With this, the reaction layer is removed. After that, the processing returned to the start, and cooling was performed with Ar caused to flow at a pressure of 900 Pa and a flow rate of 1.4 L/min for 60 seconds. This series of processes (processes in Step S102 to Step S106) was performed for 10 cycles here along the flow of FIG. 5.

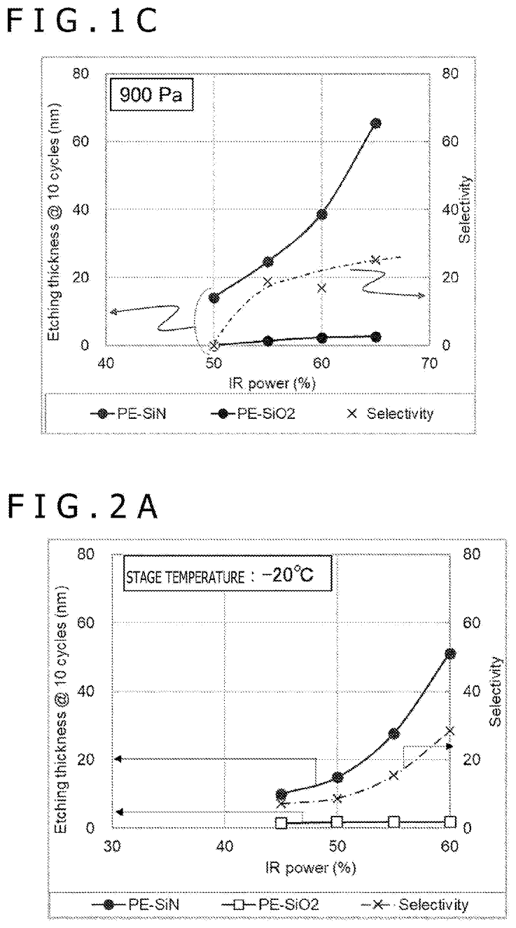

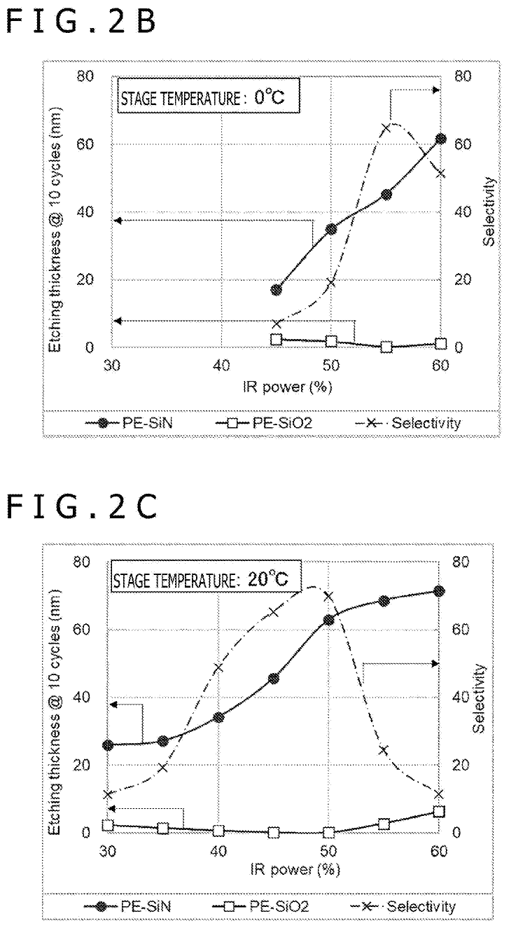

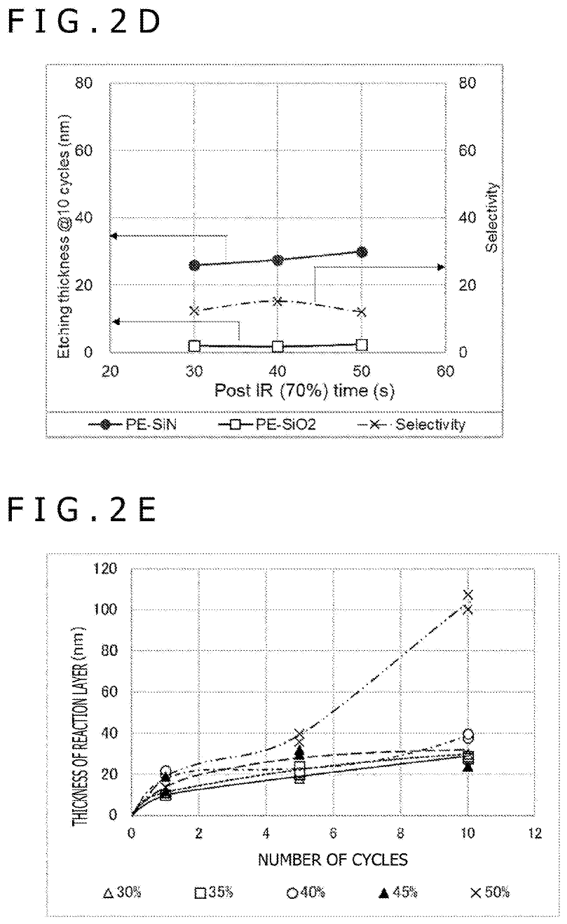

The etching film thickness of the silicon nitride film (PE-SiN) and the etching film thickness of the silicon oxide film (PE-SiO2) obtained after 10 cycles, as well as the selectivity of the silicon nitride film with respect to the silicon oxide film, with respect to different outputs of the IR lamp 60, are illustrated in FIG. 2A, FIG. 2B, and FIG. 2C. FIG. 2A is a graph illustrating the etching film thicknesses of silicon nitride film and silicon oxide film, as well as the selectivity, with respect to the IR lamp output emitted simultaneously with HF supply in a first process according to a second embodiment (stage temperature of −20° C., total pressure of 900 Pa, and 10 cycles). FIG. 2B is a graph illustrating the etching film thicknesses of silicon nitride film and silicon oxide film, as well as the selectivity, with respect to the IR lamp output emitted simultaneously with HF supply in the first process according to the second embodiment (stage temperature of 0° C., total pressure of 900 Pa, and 10 cycles). FIG. 2C is a graph illustrating the etching film thicknesses of silicon nitride film and silicon oxide film, as well as the selectivity, with respect to the IR lamp output emitted simultaneously with HF supply in the first process according to the second embodiment (stage temperature of 20° C., total pressure of 900 Pa, and 10 cycles). Here, FIG. 2A, FIG. 2B, and FIG. 2C illustrate the experimental results for the respective different temperatures of the stage 3, namely, −20° C., 0° C., and 20° C. Further, the emission of the IR lamp 60 for removing the reaction layer was performed at an output of 70% for 40 seconds.

With the use of the wafer 2 having attached thereto a thermocouple, the process temperatures during lamp emission were actually measured by substituting HF gas with Ar. Table 2A describes the IR lamp output. (IR output) and the temperature after 60 seconds for different stage temperatures. Table 2B describes the temperature after 40 seconds at an IR lamp output of 70%. It was found that the temperature was from 21° C. to 81° C. as indicated by the reached temperatures in Table 2A. Further, the temperatures in the reaction layer removal process were also measured, and it was found that the temperatures were the reached temperatures described in Table 2B.

TABLE 2A

| Stage | | | | | | |
|---|---|---|---|---|---|---|
| temperature | IR output (%) | | | | | |
| (° C.) | 35 | 40 | 45 | 50 | 55 | 60 |
| −20 | — | — | 21° C. | 33° C. | 48° C. | 63° C. |
| 0 | — | — | 39° C. | 50° C. | 65° C. | 81° C. |
| 20 | 40° C. | 47° C. | 59° C. | 70° C. | — | — |

TABLE 2B

| | | | |
|---|---|---|---|
| Stage temperature (° C.) | −20 | 0 | 20 |
| Reached temperature (° C.) | 70 | 83 | 95 |

When FIG. 2A, FIG. 2B, and FIG. 2C are referred to, it is obvious that as the output of the IR lamp 60 (IR output) increases, the etching film thickness of the silicon nitride film (PE-SiN) increases. Further, it is found that as the temperature of the stage 3 increases, the graph of the etching amount of the silicon nitride film (PE-SiN) shifts to the left, which indicates that the same etching amount is obtained with a lower output of the IR lamp 60 (IR output). However, it is found that when the temperature of the stage 3 is high, the etching amount of the silicon oxide film (PE-SiO2) tends to increase at a high output of the IR lamp 60, resulting in a decrease in selectivity.

Here, in etching the silicon nitride film 103 in the lateral direction, the selectivity with respect to the silicon oxide film 102 is desirably 10 or higher, and more desirably 20 or higher. When the selectivity is low, the portion of the silicon oxide film 102, which is not intended to be etched originally, is etched simultaneously, and hence the shape of the end portion of the silicon oxide film 102 after etching is not rectangular but rounded, as indicated by 111 of FIG. 11A, which adversely affects the device performance.

Empirically, when the selectivity is 10 or higher, and more desirably 20 or higher, a shape closer to a rectangle as illustrated in FIG. 10B is obtained. Further, when the selectivity is lower than 5, the shape of the end portion of the silicon oxide film 102 is rounded as indicated by 111 of FIG. 11A, which is undesirable.

Here, similar to Example 1, with the use of a sample obtained by forming a 200 nm slit-shaped space in a sample including a total of 20 alternating layers of the silicon nitride film 103 (film thickness of 40 nm) and the silicon oxide film 102 (film thickness of 40 nm), the etching characteristics with fine patterns were evaluated. The slit sample was etched for 10 cycles under the experimental conditions of the conditions used in FIG. 2A, FIG. 2B, and FIG. 2C. The results are described in Table 2C, Table 2D, and Table 2E. Table 2C describes the etching results at a stage temperature of −20° C. and 900 Pa. Table 2D describes the etching results at a stage temperature of 0° C. and 900 Pa. Table 2E describes the etching results at a stage temperature of 20° C. and 900 Pa.

As a result, when etching progressed with high selectivity and a shape closer to a rectangle as illustrated in FIG. 108, there was a case where the selectivity was poor and the distal end of the silicon oxide film, which was intended to remain rectangular, was rounded as illustrated in FIG. 11A. There was observed a case where although the selectivity was relatively good, the corners of the silicon oxide film were rounded off to form a triangular shape as illustrated in FIG. 11B. Moreover, there was observed a result in which while the corners of the silicon oxide film remained to maintain the rectangular shape, the film thickness of the silicon oxide film portion was thinned as illustrated in FIG. 12.

Thus, Table 2C, Table 2D, and Table 2E describe the recess amount (obtained by subtracting the etching amount of the silicon oxide film from the etching amount of the silicon nitride film), the selectivity based on the result of the slit pattern (obtained by dividing the etching amount from the initial dimensions of the silicon nitride film by the etching amount of the silicon oxide film), and the remaining SiO2 thickness (obtained by dividing the thickness 108 of the distal end of the silicon oxide film after etching illustrated in FIG. 12 by the initial thickness 107 of the silicon oxide film). Here, good etching conditions include a relatively large recess amount, high selectivity, and a remaining SiO2 thickness with a value close to 1:

Note that, to make the evaluation results easier to understand, symbols such as ⊚, ∘, Δ, and x are included in Table 2C, Table 2D, and Table 2E. The criteria for the symbols are described in Table 1E described earlier.

TABLE 2C

| | | | | |
|---|---|---|---|---|
| IR output (%) | 45 | 50 | 55 | 60 |
| Temperature (° C.) | 21 | 33 | 48 | 63 |
| Recess amount (nm) | ◯ 16.1 | ⊚ 22.8 | ⊚ 40.2 | ⊚ 60.3 |
| Selectivity | X 4.44 | ◯ 5.45 | ◯ 8.57 | ⊚ 13.0 |
| Remaining SiO2 | ⊚ 0.952 | ◯ 0.893 | ◯ 0.893 | X 0.714 |
| thickness | | | | |

TABLE 2D

| | | | | |
|---|---|---|---|---|
| IR output (%) | 45 | 50 | 55 | 60 |
| Temperature | 39 | 50 | 65 | 81 |
| (° C.) | | | | |
| Recess | ⊚ 30.3 | ⊚ 45.4 | ⊚ 62.8 | ⊚ 83.3 |
| amount (nm) | | | | |
| Selectivity | ⊚ 24.8 | ⊚ 31.0 | ⊚ 10.6 | ◯ 7.06 |
| Remaining SiO2 | ◯ 0.833 | ◯ 0.833 | X 0.714 | X 0.595 |
| thickness | | | | |

TABLE 2E

| | | | | |
|---|---|---|---|---|
| IR output (%) | 35 | 40 | 45 | 50 |
| Temperature (° C.) | 40 | 47 | 59 | 70 |
| Recess amount (nm) | ⊚ 34.7 | ⊚ 42.7 | ⊚ 57.3 | ⊚ 66.2 |
| Selectivity | ◯ 8.22 | ◯ 9.05 | ⊚ 14.4 | ◯ 8.77 |
| Remaining SiO2 | Δ 0.774 | Δ 0.774 | X 0.714 | X 0.655 |
| thickness | | | | |

As described in Table 2° C., Table 20, and Table 25, #s the stage temperature is higher, the appropriate output of the IR lamp 50 is smaller. Further, in all cases, when the output of the IR lamp 60 is high, the remaining SiO2 thickness is small. It was found that a high IR Lams output was hot suitable for a condition. Thus, it was found that the remaining Side thickness was small in some cases even when the selectivity was relatively high. Further, as a matter of course, the selectivity was poor when the IR output was too low as in the case with a stage temperature of −20° C. and an IR output of 45%. From the above, it was found that the temperature that achieved the satisfactory recess amount, selectivity, and remaining SiO2 thickness was 30° C. or higher and 55° C. or lower.

Moreover, when Table 2C, Table 2D, and Table 2E were compared in terms of the remaining SiO2 thickness, it was found that the remaining SiO2 thickness was larger with the lower stage temperature described in Table 2C (stage temperature of −20° C.) and smaller with the higher stage temperature described in Table 2E (stage temperature of 20° C.). Thus, it was found that it was desirable to set the stage 3 at a low temperature and obtain the required reaction temperature through the emission of the IR lamp 60.

The temperature during the second emission of the IR lamp 60 for removing the reaction layer in this experiment was in the range of 70° C. to 95° C. as described in Table 2B. However, within this temperature range, no significant difference was observed. Moreover, in this experiment, under the conditions of a stage temperature of −20° C. and an IR output of 55%, which achieved relatively good performance, in the exhaust process for hydrogen fluoride gas and reaction products of FIG. 5 (Step S104), exhaustion was performed with Ar caused to flow at 1.4 L/min and the exhaust valve in the pressure adjustment means 14 fully open for 120 seconds, instead of vacuum exhaustion. As a result, it was found that the effect of reducing a residue on fine patterns was better than that in the case of performing vacuum exhaustion.

Next, with the use of the process condition considered with FIG. 2A described earlier (stage temperature of −20° C.), etching was performed for 10 cycles along the flow of FIG. 5 with the output of the IR lamp 60 for the first process of reaction layer formation (Step S103) fixed at 55%, and different emission times of the IR lamp 60 (output of 70%) for the second process of reaction layer removal (Step 105) (post IR (70%) time), namely, 20 seconds, 30 seconds, 40 seconds, and 50 seconds.

The etching film thickness of the silicon nitride film (PE-SiN) and the etching film thickness of the silicon oxide film (PE-SiO2) obtained after 10 cycles, as well as the selectivity of the silicon nitride film with respect to the silicon oxide film, with respect to the time of IR lamp emission for reaction layer removal in Step 105 (post IR), are illustrated in FIG. 2D. FIG. 2D is a graph illustrating the etching film thicknesses of silicon nitride film and silicon oxide film, as well as the selectivity, with respect to the emission time of the emission of the IR lamp in the second process according to the second embodiment (stage temperature of 0° C., total pressure of 900 Pa, and 10 cycles). As the experimental results, with 20 seconds of IR emission for reaction layer removal, the removal of the reaction layer did not work well, and the film thickness was not able to be measured with an optical film thickness measurement device. As is found from FIG. 2D, no significant difference was observed in the results for 30 seconds to 50 seconds of IR emission for reaction layer removal in Step 105.

Here, similar to the preceding consideration, with the use of a sample obtained by forming a 200 nm slit-shaped space in a sample including a total of 20 alternating layers of the silicon nitride film 103 (film thickness of 40 nm) and the silicon oxide film 102 (film thickness of 40 nm), the etching characteristics with fine patterns were evaluated. The slit sample was etched for 10 cycles under the experimental conditions of the conditions used in FIG. 2D. The results are described in Table 2F. Table 2F describes the etching results with different emission times of IR for reaction layer removal (reaction layer removal IR) . . .

TABLE 2F

| | | | | |
|---|---|---|---|---|
| Reaction layer removal | 20 | 30 | 40 | 50 |
| IR (s) | | | | |
| Reaction layer removal | 61 | 72 | 83 | 91 |
| temperature (° C.) | | | | |
| Recess amount (nm) | NG | ⊚ 39.5 | ⊚41.0 | ⊚ 66.0 |
| Selectivity | NG | ◯ 7.35 | ◯ 8.59 | ◯ 8.01 |
| Remaining SiO2 | NG | ◯ 0.833 | ◯ 0.893 | ◯ 0.893 |
| thickness | | | | |

The results were all good for IR emission times for reaction layer removal (reaction layer removal IR) of 30 seconds, 40 seconds, and 50 seconds. In contrast to this, with 20 seconds of reaction layer removal IR, as described earlier, the reaction layer was not able to be removed, and etching did not work well. From this result, it was found that when the temperature for reaction layer removal was too low, the reaction layer was not removed, and etching did not work well.

As described later, it is conceivable that the reaction product mainly contains ammonium hexafluorosilicate [(NH₄)₂SiF₆]. Thus, a certain degree of temperature is required for decomposition and volatilisation. However, since there is a possibility of side reactions such as the etching of the silicon oxide film 102 when the temperature is too high, it is desirable to have the minimum necessary temperature. From the above, the second temperature for reaction layer removal is desirably 70° C. or higher and 110° C. or lower, and more desirably 75° C. or higher and 100° C. or lower, for example.

### [Consideration on Thickness and Composition of Reaction Layer]

Next, the thickness of the reaction layer was considered. Here, under the conditions of the etching conditions illustrated in FIG. 2C and Table 2E (stage temperature of 20° C., 900 Pa, HE/Ar=0.40/0.20 L/min, and 60 seconds), cycle processing that had different IR emission conditions for reaction layer formation (output of IR lamp 60) of 30% to 50% and only excluded performing IR emission for reaction layer removal (emission time of IR for reaction layer removal (reaction layer removal IR)) was performed. Specifically, the cycle along the flow of FIG. 5 in which after the exhaustion of hydrogen fluoride gas and reaction product (Step S104) had been performed, the processing proceeded to the next step of wafer cooling (Step S106) without the removal of the reaction layer by heating (Step S105) and then restarted from diluent gas introduction (S102) was repeated (that is, the sequence of S102→S103→S104→S106, which formed one cycle, was repeated a plurality of times). Samples of silicon nitride films subjected to the cycle without IR emission for reaction layer removal two times, five times, and ten times were prepared, and the cross-sections thereof were observed with a scanning electron microscope to measure the thicknesses of the reaction layers. The results are illustrated in FIG. 2E. FIG. 2E is a graph illustrating the thickness of the reaction layer on a silicon nitride film with respect to the number of cycles with different levels of the IR lamp output emitted simultaneously with HF supply in the first process according to the second embodiment.

FIG. 2E illustrates the investigation results of the thickness of the reaction layer with respect to the number of cycles at a stage temperature of 20° C. The data obtained with different outputs of the IR lamp 60 for reaction layer formation of 30% to 50% (here, IR outputs of 30%, 35%, 40%, 45%, and 50%) is organized. The stage temperature with respect to the IR output is organized in Table 2A. It was found that when the IR output was from 30% to 45%, the thickness of the reaction layer tended to saturate with respect to the number of cycles. It was found that, in contrast to this, when the IR output was 50%, the thickness of the reaction layer tended to significantly increase with respect to the number of cycles. In terms of temperature, it was found that between 40° C. and lower than 60° C. (IR lamp output of 30% to 45%), the thickness of the reaction layer tended to saturate, and that at a temperature of 70° C. (IR lamp output of 50%), the reaction layer tended to continue to increase with respect to the number of cycles.

As indicated by the etching results for fine patterns in Table 2E, under the condition of a stage temperature of 20° C., good results were obtained at IR outputs of 35% and 40%. When the thickness of the reaction layer described earlier is considered, it is conceivable that if the thickness of the generated reaction layer is too large (in the case of an IR output of 50%), the amount of the reaction layer to be removed through decomposition and volatilization with the second IR emission is too large, resulting in the thin shape and degradation of the adjacent silicon oxide film 102. Thus, it is important to control not only the temperature for the formation and removal of the reaction layer but also the generation amount of the reaction layer. It is conceivable from FIG. 2E described earlier that the thickness of the reaction layer is desirably 50 nm or less after 10 cycles, for example. Thus, in Step S103, which is the first process, it is desirable to form a reaction layer of 5 nm or less per cycle, for example.

With regard to the above-mentioned reaction layer, compositional analysis was performed by X-ray photoelectron spectroscopy (XPS). As a result, in terms of surface composition, nitrogen (N1s) exhibited a peak at 402 eV rather than 395 eV, which corresponded to silicon nitride. This peak at 402 eV was found to belong to ammonium salts. Also for silicon (Si2P), with silicon nitride at 99 eV, a peak belonging to silicate at 103 eV was observed, and the silicon was thought to be hexafluorosilicate SiF₆²⁻. The elemental ratio of the case of ammonium hexafluorosilicate [(NH₄)₂SiF₆] is Si=1, F=6, and N=2. It was found that the elemental ratio obtained from XPS of the surface of the reaction layer was Si=1, F=4.4, and N=1.6, which was close to that elemental ratio. From the above, it is conceivable that the component generated as the reaction layer mainly contains ammonium hexafluorosilicate [(NH₄)₂SiF₆], and that HE or NH₃ generated during the decomposition and volatilization of the reaction layer etches the adjacent silicon oxide film depending on the conditions.

### Example 3

### [Etching Method: Process Flow 3 of Dry Etching]

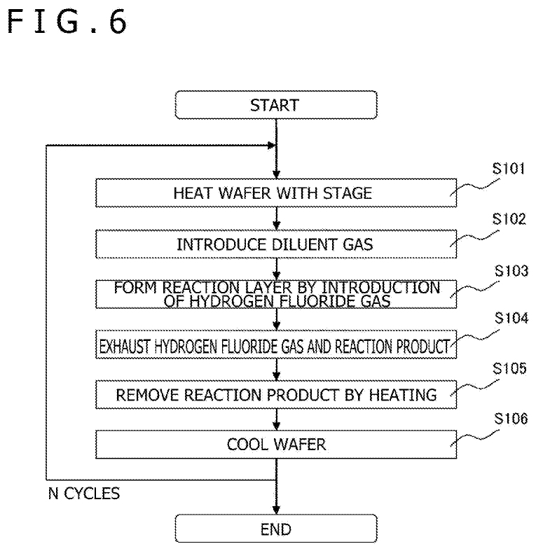

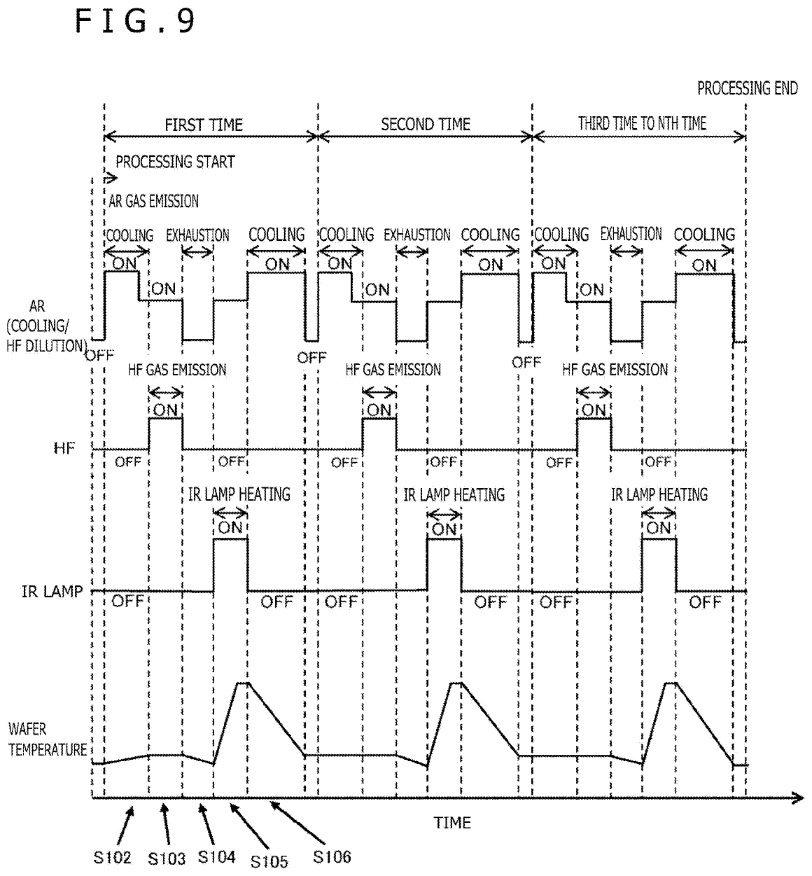

Next, a flow of an etching process with hydrogen fluoride gas without using plasma proposed in Example 3 of the present embodiment, which is partially different from Flow 1 of the etching process described in Example 1, is described with reference to FIG. 4, FIG. 6, and FIG. 9. FIG. 6 is a flow chart of an etching method for a silicon nitride film according to the embodiment. FIG. 9 is a time chart schematically illustrating a flow of operations with the passage of time of etching processing according to the third example.

First, the wafer 2 is transferred to the processing chamber 1 through the transfer port (not illustrated) provided in the processing chamber 1, and then the wafer 2 is loaded on the protrusions 56 of the wafer stage 3. In this case, as the stage temperature, a predetermined temperature of 30° C. to 55° C. is set.

After that, Ar gas for thermal conduction is supplied to the wafer 2 through the mass flow controller 50, the gas distributor 51, and the shower plate 23, to thereby perform wafer heating with the stage in Step S101 of FIG. 6. Since Ar gas plays both the role of heat conduction to the wafer 2 and the role of a diluent gas for diluting HF gas, here, Step S101 and Step S102 of FIG. 6 are performed simultaneously. Note that, the flow rate of Ar gas can be changed for heat conduction to the wafer 2 and for use as a diluent gas. Further, it is possible to continue causing Ar gas for dilution to flow until the etching processing ends or to stop the flow. Further, instead of Ar gas, N₂ gas can be used as an inert gas.

Subsequently, as Step S103 of FIG. 6, a predetermined amount of HF gas was supplied to the processing chamber 1 for a predetermined time to form a reaction layer. Here, heating with an infrared (IR) lamp as described with the flow of FIG. 5 is not used, and only the temperature of the heat conduction by the stage 3 is used. The temperature of the stage 3, that is, the temperature of the wafer 2 is desirably 30° C. or higher and 55° C. or lower, and more desirably 35° C. or higher and 50° C. or lower, for example. The film thickness of the reaction layer can be controlled by controlling the temperature of the stage 3, the total pressure or the HF partial pressure, the time, and the number of repetitions, for example.

In the present embodiment, the pressure used is desirably approximately 10 Pa to approximately 1,000 Pa, more desirably 50 Pa to 1,000 Pa (50 Pa or higher and 1,000 Pa or lower), and particularly desirably 300 Pa to 1,000 Pa, for example. The higher the pressure, the easier it is to form a reaction layer on the silicon nitride film and the lower the required temperature for formation.

After a predetermined time for the formation of the reaction layer, as Step S104 of FIG. 6, the supply of HF gas is stopped, and the residual HF gas in the gas phase and the reaction product present on the silicon nitride film as the reaction layer are exhausted. In Step S104, by supplying Ar gas, which is a diluent gas, during and after the exhaustion, the reaction product can be more efficiently exhausted.

Next, heating is performed without causing HE gas to flow to remove the reaction layer (Step S105 of FIG. 6). The heating temperature here is desirably 70° C. to 110° C. (70° C. or higher and 110° C. or lower), and more desirably 70° C. to 100° C. (70° C. or higher and 100° C. or lower), for example. As the heating method, here, the IR lamp 60 was used. The heating method is not limited to this and may be, for example, a method of heating the wafer stage 3 or a method of separately transferring a wafer to an apparatus configured to perform only heating, thereby performing heating processing. Further, during the emission of the IR lamp 60, Ar gas or nitrogen gas can be introduced. Further, heating processing can be performed a plurality of times as needed. After heating, the cooling of the wafer 2 (wafer cooling) in Step S106 is performed. After this, the cycle including the processes in Step S102 to Step S106 is repeated N times (N is a positive integer). After repeating the cycle until the required etching amount is obtained, the flow of FIG. 6 ends.

The time chart of FIG. 9 illustrates the flow illustrated in FIG. 6. The process of causing HF gas and Ar to flow (reaction layer formation process: S103) and the process of performing IR lamp heating without causing HE gas to flow (reaction layer decomposition and volatilization process: S105) are included in one cycle, and the cycle is repeated N times to etch the silicon nitride film.

### [Etching Result 3]

With the use of the etching processing apparatus 100 used in Example 1 and the etching process flow of FIG. 6, a process that included setting the temperature of the stage 3 (stage temperature) to 20° C. to 40° C. and causing HF/Ar to flow in Step S103 without performing IR heating was considered. First, for heat conduction to the wafer 2, Ar was caused to flow at a flow rate of 1.4 L/min and 900 Pa for 60 seconds. After that, while the pressure was controlled at 900 Pa, HE was introduced at a flow rate of 0.40 L/min and Ar was introduced as a diluent gas at a flow rate of 0.20 L/min for 60 seconds. With this, a reaction layer is formed on the silicon nitride film 103.

After that, with the exhaust valve in the pressure adjustment means 14 fully open, exhaustion was performed for 120 seconds. With this exhaustion operation, some of the fluorine gas and reaction product are exhausted. Next, with the stage 3 at the set temperature unchanged (20° C. to 40° C.), Ar caused to flow at a flow rate of 0.50 L/min, and the exhaust valve in the pressure adjustment means 14 fully open, heating was performed with the IR lamp 60 at an output of 70% for 30 seconds. With this, the reaction layer is removed. After that, the processing returned to the start, and the wafer 2 was cooled with Ar caused to flow at a pressure of 900 Pa and a flow rate of 1.4 L/min for 60 seconds to reach the same temperature as the temperature of the stage 3. This series of processes was performed for 10 cycles here along the flow of FIG. 6.

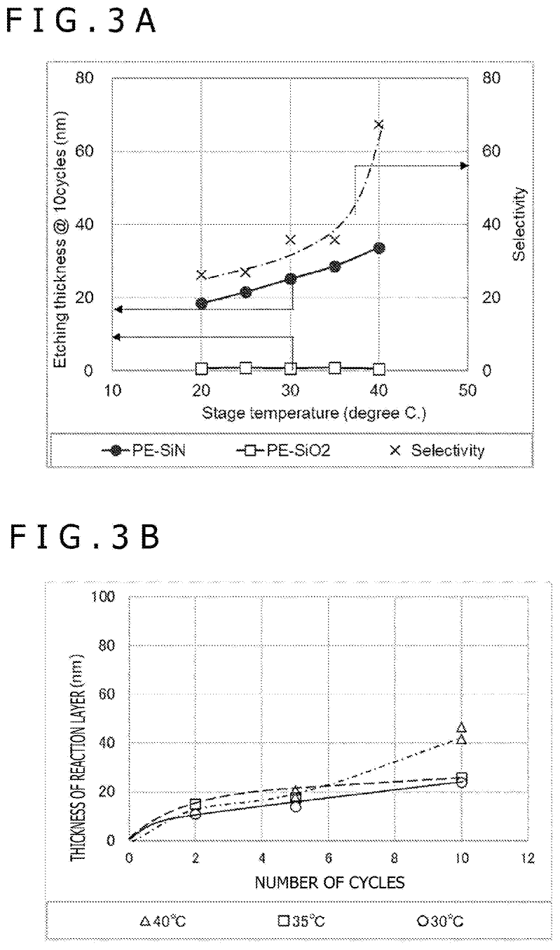

The etching film thickness of the silicon nitride film (PE-SiN) and the etching film thickness of the silicon oxide film (PE-SiO2) obtained after 10 cycles, as well as the selectivity of the silicon nitride film (PE-SiN) with respect to the silicon oxide film (PE-SiO2), with respect to different temperatures of the stage 3, are illustrated in FIG. 3A. FIG. 3A is a graph illustrating the etching film thicknesses of silicon nitride film and silicon oxide film, as well as the selectivity, with different stage temperatures in a first process according to a third embodiment.

As illustrated in FIG. 3A, it was found that the silicon nitride film (PE-SiN) was etched even with the stage temperature alone, and that the etching amount of the silicon nitride film (PE-SiN) was proportional to the stage temperature. Further, the silicon oxide film (PE-SiO2) was hardly etched, and the selectivity of the monolayer film was high.

Here, similar to Examples 1 and 2, with the use of a sample obtained by forming a 200 nm slit-shaped space in a sample including a total of 20 alternating layers of the silicon nitride film 103 (film thickness of 40 nm) and the silicon oxide film 102: (film thickness of 40 nm), the etching characteristics with fine patterns were evaluated. The slit sample was etched for 10 cycles and 20 cycles under the experimental conditions of the conditions used in FIG. 3A. The results are described in Table 3. Table 3 describes the etching results for fine patterns under the conditions of FIG. 3A.

TABLE 3

| | Stage temperature (° C.) | | | | | |
|---|---|---|---|---|---|---|
| | 40 | 40 | 35 | 35 | 30 | 30 |
| Number of cycles | 10 | 20 | 10 | 20 | 10 | 20 |
| Recess amount (nm) | ⊚ 23.8 | ⊚ 48.9 | ◯ 19.7 | ⊚ 40.7 | ⊚ 22.4 | ⊚ 46.9 |
| Selectivity | ◯ 7.84 | X 2.78 | ◯ 8.34 | X 2.30 | ◯ 9.35 | X 4.09 |
| Remaining SiO2 thickness | ◯ 0.833 | Δ 0.774 | ◯ 0.833 | ◯ 0.833 | ◯ 0.833 | ◯ 0.833 |

Thus, Table 3 describes the stage temperature, the number of cycles, the recess amount (obtained by subtracting the etching amount of the silicon oxide film from the etching amount of the silicon nitride film), the selectivity based on the result of the slit pattern (obtained by dividing the etching amount from the initial dimensions of the silicon nitride film by the etching amount of the silicon oxide film), and the remaining SiO2 thickness (obtained by dividing the thickness 108 of the distal end of the silicon oxide film 102 after etching illustrated in FIG. 12 by the initial thickness 107 of the silicon oxide film 102). Here, good etching conditions include a relatively large recess amount, high selectivity, and a remaining SiO2 thickness with a value close to 1.

Note that, to make the evaluation results easier to understand, symbols such as ⊚, ∘, Δ, and x are included in Table 3. The criteria for the symbols are described in Table 1E described above.

As the results, it was found that in all cases, when etching was performed for the increased number of cycles, namely, 20 cycles, the selectivity decreased. In particular, when the number of cycles was large, there was observed a tendency that the corners of the silicon oxide film 102 were rounded off to form a triangular distal end as the shape indicated by 113 of FIG. 11B.

It was found that although the silicon nitride film 103 was able to be etched through reaction with HE with the temperature of the stage 3 alone, etching with the combination of cooling with the stage 3 at low temperature and the IR lamp 60 as described earlier in Examples 1 and 2 was superior in selectivity and pattern shape. That is, with regard to the first process (Step S103) and the second process (Step S105), it is preferable that the stage 3 on which the wafer 2 is placed be set to a low temperature of −50° C. or higher and 0° C. or lower and the wafer 2 be heated with the IR lamp 60 to obtain a temperature of 30° C. or higher and 55° C. or lower for the first process and a temperature of 70° C. or higher and 110° C. or lower for the second process.

### [Consideration on Thickness of Reaction Layer]

Next, similar to Example 2, the thickness of the reaction layer was considered. Here, under the conditions of the etching conditions illustrated in FIG. 3A and Table 3 (stage temperature of 20° C. to 40° C., 900 Pa, HF/Ar=0.40/0.20 L/min, and 60 seconds), cycle processing that only includes performing reaction layer formation and only excludes performing IR emission for reaction layer removal was performed. Specifically, the cycle along the flow of FIG. 6 in which after the exhaustion of hydrogen fluoride gas and reaction product (Step S104) had been performed, the processing proceeded to the next step of wafer cooling (Step S106) without the removal of the reaction layer by heating (Step S105) and then started from diluent gas introduction (S102) was repeated (that is, the sequence of S101→S102→S103→S104→S106, which formed one cycle, was repeated a plurality of times). Samples of silicon nitride films subjected to the cycle without IR emission for reaction layer removal two times, five times, and ten times were prepared, and the cross-sections thereof were observed with a scanning electron microscope to measure the thicknesses of the reaction layers. The results are illustrated in FIG. 38. FIG. 3B is a graph illustrating the thickness of the reaction layer on a silicon nitride film with respect to the number of cycles with different stage temperatures in the first process according to the third embodiment.

FIG. 3B illustrates the investigation results of the thickness of the reaction layer with respect to the number of cycles at stage temperatures of 30° C., 35° C., and 40° C. It is found that the thickness of the reaction layer tends to saturate with respect to the number of cycles at stage temperatures of 30° C. and 35° C. It was found that, at a stage temperature of 40° C., the thickness of the reaction layer tended to slightly increase with respect to the number of cycles.

As described in Example 2, when the thickness of the generated reaction layer is too large, the amount of the reaction layer to be removed through decomposition and volatilisation with the second IR emission is too large, resulting in the thin shape and degradation of the adjacent silicon oxide film 102. Thus, it is important to control not only the temperature for the formation and removal of the reaction layer but also the generation amount of the reaction layer. When FIG. 2E of Example 2 described earlier is also considered, the thickness of the reaction layer is desirably 50 nm or less after 10 cycles, for example. Thus, in Step S103, which is the first process, it is desirable to form a reaction layer of 5 nm or less per cycle.

### DESCRIPTION OF REFERENCE CHARACTERS

1: Processing chamber
2: Wafer
3: Wafer stage
11: Base chamber
12: Quartz chamber
13: Discharge area
14: Pressure adjustment means
15: Exhaust means
16: Vacuum exhaust pipe
20: ICP coil
21: High-frequency power supply
22: Matching unit
23: Shower plate
24: Gas dispersion plate
25: Top plate
26: Slit plate
27: Flow path
30: Electrode for electrostatic adsorption
31: DC power supply for electrostatic adsorption
38: Chiller
39: Flow path for coolant
50: Mass flow controller
51: Gas distributor
54: Valve
55: He gas
56: Protrusion portion for proximity cooling
60, 60-1, 60-2, 60-9: IR lamp
61: Reflecting plate
64: IR lamp power supply
70: Thermocouple
71: Thermocouple thermometer
72: IR light transmission window
73: IR lamp power supply
74: High-frequency cut filter
101: Substrate
102: Silicon nitride film
103: Silicon oxide film
104: Opening
105: Film stack
106: Etching amount of silicon oxide film with respect to silicon nitride film
111: End portion of silicon oxide film after etching when selectivity is low
112: An illustration of an exemplary end portion of a silicon oxide film after etching, in which, while the corners of the silicon oxide film have remained to maintain the rectangular shape, the film thickness of the silicon oxide film portion has been thinned
113: An illustration of an exemplary end portion of a silicon oxide film after etching, in which the corners of the silicon oxide film have been rounded off to form a triangular shape

1. An etching method of dry etching a film structure which is formed in advance on a wafer disposed in a processing chamber and in which an end portion of a film stack including a silicon nitride film and silicon oxide films vertically sandwiching the silicon nitride film forms a sidewall of a trench or hole, by supplying a gas for processing into the processing chamber, without using plasma, the etching method comprising:
forming, as a first process, a reaction layer on the silicon nitride film by reaction of hydrogen fluoride gas at 30° C. or higher and 55° C. or lower;
removing, after the first process, as a second process, the reaction layer having been formed in the first process, through volatilization by performing heating at 70° C. or higher and 110° C. or lower without causing the hydrogen fluoride gas to flow; and
etching the silicon nitride film from the end portion in a lateral direction by performing the first process and the second process a plurality of times.

2. The etching method according to claim 1, wherein
the heating in the second process includes lamp heating.

3. The etching method according to claim 1 or 2, wherein
with regard to the first process and the second process, a stage on which the wafer is placed is set to a low temperature of −50° C. or higher and 0° C. or lower, and the wafer is subjected to lamp heating to thereby obtain a temperature of 30° C. or higher and 55° C. or lower for the first process and a temperature of 70° C. or higher and 110° C. or lower for the second process.

4. The etching method according to claim 1 or 2, wherein
a pressure in the first process is 50 Pa or higher and 1,000 Pa or lower.

5. The etching method according to claim 1 or 2, wherein
between the first process and the second process, a process of performing exhaustion while causing an inert gas to flow is included.

6. The etching method according to claim 1 or 2, wherein
the reaction layer formed in the first process has a thickness of 5 nm or less.
